(19) United States
(12) Patent Application Publication
(10) Pub. No.: US 2022/0278700 A1
(43) Pub. Date: Sep. 1, 2022

(54) FILTER, ANTENNA MODULE, AND RADIATING ELEMENT

(71) Applicant: Murata Manufacturing Co., Ltd., Nagaokakyo-shi (JP)

(72) Inventors: Hirotsugu MORI, Nagaokakyo-shi (JP); Yoshinori TAGUCHI, Nagaokakyo-shi (JP)

(73) Assignee: Murata Manufacturing Co., Ltd., Nagaokakyo-shi (JP)

(21) Appl. No.: 17/746,998

(22) Filed: May 18, 2022

Related U.S. Application Data
(63) Continuation of application No. PCT/JP2020/038960, filed on Oct. 15, 2020.

(30) Foreign Application Priority Data
Nov. 19, 2019 (JP) 2019-208801

(51) Int. Cl. H04B 1/00; H01Q 5/335; H01Q 5/328; H04B 1/10

(52) U.S. Cl. CPC H04B 1/006; H01Q 5/335; H01Q 5/328; H04B 1/1036

(57) ABSTRACT

A reduction in size and cost of a filter capable of changing a pass band is realized. A filter includes a first distributed constant line, a first impedance element, a second impedance element, and a first switch. The first impedance element and the first switch are connected in series between the first distributed constant line and a ground point. The second impedance element is connected between the first distributed constant line and the ground point.

### CROSS-REFERENCE TO RELATED APPLICATIONS

The present application is a continuation application of International Patent Application No. PCT/JP2020/038960, filed Oct. 15, 2020, which claims priority to Japanese Patent Application No. 2019-208801, filed Nov. 19, 2019, the entire contents of each of which being incorporated herein by reference.

### TECHNICAL FIELD

The present disclosure relates to a filter capable of changing a pass band, an antenna module including the filter, and a radiating element.

### BACKGROUND ART

In the past, a filter capable of changing a pass band has been known. For example, Japanese Unexamined Patent Application Publication No. 2015-144372 (Patent Document 1) discloses a tunable filter capable of reducing an insertion loss while suppressing a decrease in Q value of a resonator.

### CITATION LIST

Patent Document
Patent Document 1: Japanese Unexamined Patent Application Publication No. 2015-144372

### SUMMARY

### Technical Problem

In the tunable filter disclosed in Patent Document 1, electrostatic capacity of an electromagnetic field perturbation element such as a variable capacitor is changed to change a pass band of the tunable filter. However, a size of the electromagnetic field perturbation element disclosed in Patent Document 1 is relatively large, and a cost of the electromagnetic field perturbation element is relatively high.

The present disclosure has been made to solve the above-described problems, and an object thereof is to realize a reduction in size and cost of a filter capable of changing a pass band.

### Solution to Problem

A filter according to the present disclosure includes a first distributed constant line, a first impedance element, a second impedance element, and a first switch. The first impedance element and the first switch are connected in series between the first distributed constant line and a ground point. The second impedance element is connected between the first distributed constant line and the ground point.

### Advantageous Effects

According to a filter according to an embodiment of the present disclosure, a first impedance element and a first switch are connected in series between a first distributed constant line and a ground point, and a second impedance element is connected between the first distributed constant line and the ground point, and thus it is possible to realize a reduction in size and cost of a filter capable of changing a pass band.

### BRIEF DESCRIPTION OF DRAWINGS

FIG. 1 is an equivalent circuit diagram of a filter according to Embodiment 1.

FIG. 2 is a perspective view of structure of the filter in FIG. 1.

FIG. 3 is a plan view of the filter in FIG. 2 viewed in a Y-axis direction.

FIG. 4 is a graph showing bandpass characteristics of the filter in FIG. 1.

FIG. 5 is an equivalent circuit diagram of a filter according to Comparative Example 1.

FIG. 6 is a graph showing bandpass characteristics of the filter in FIG. 5.

FIG. 7 is an equivalent circuit diagram of a filter according to Comparative Example 2.

FIG. 8 is an equivalent circuit diagram of a filter according to Comparative Example 3.

FIG. 9 is a graph showing the bandpass characteristics of the filter in FIG. 1, bandpass characteristics of the filter in FIG. 7, and bandpass characteristics of the filter in FIG. 8.

FIG. 10 is a perspective view of structure of a filter according to Modification Example 1 of Embodiment 1.

FIG. 11 is a perspective view of structure of a filter according to Modification Example 2 of Embodiment 1.

FIG. 12 is a perspective view of structure of a filter according to Modification Example 3 of Embodiment 1.

FIG. 13 is a perspective view of structure of a filter according to Modification Example 4 of Embodiment 1.

FIG. 14 is a plan view of the filter in FIG. 13 viewed in the Y-axis direction.

FIG. 15 is a perspective view of structure of a filter according to Modification Example 5 of Embodiment 1.

FIG. 16 is a plan view of the filter in FIG. 15 viewed in the Y-axis direction.

FIG. 17 is an equivalent circuit diagram of a filter according to Modification Example 6 of Embodiment 1.

FIG. 18 is an equivalent circuit diagram of a filter according to Modification Example 7 of Embodiment 1.

FIG. 19 is a plan view of structure of the filter in FIG. 18 viewed in the Y-axis direction.

FIG. 20 is a perspective view of structure of a filter according to Modification Example 8 of Embodiment 1.

FIG. 21 is an equivalent circuit diagram of a filter according to Modification Example 9 of Embodiment 1.

FIG. 22 is an equivalent circuit diagram of a filter according to Embodiment 2.

FIG. 23 is a perspective view of structure of the filter in FIG. 22.

FIG. 24 is a plan view of the filter in FIG. 23 viewed in the Y-axis direction.

FIG. 25 is a graph showing bandpass characteristics of the filter in FIG. 22.

FIG. 26 is an equivalent circuit diagram of a filter according to Comparative Example 4.

FIG. 27 is an equivalent circuit diagram of a filter according to Comparative Example 5.

FIG. 28 is a graph showing the bandpass characteristics of the filter in FIG. 22, bandpass characteristics of the filter in FIG. 26, and bandpass characteristics of the filter in FIG. 27.

FIG. 29 is a perspective view of structure of a filter according to Modification Example 1 of Embodiment 2.

FIG. 30 is an equivalent circuit diagram of a filter according to Modification Example 2 of Embodiment 2.

FIG. 31 is an equivalent circuit diagram of a filter according to Modification Example 3 of Embodiment 2.

FIG. 32 is a plan view of structure of the filter in FIG. 31 viewed in the Y-axis direction.

FIG. 33 is an equivalent circuit diagram of a filter according to Embodiment 3.

FIG. 34 is a graph showing bandpass characteristics of the filter in FIG. 33.

FIG. 35 is a graph showing bandpass characteristics of the filter in FIG. 33 when capacitance of a capacitor in FIG. 33 is reduced as compared with the case in FIG. 34.

FIG. 36 shows bandpass characteristics of a filter when each of an inductance of an inductor and the capacitance of the capacitor in FIG. 33 is larger than a value for realizing the characteristics shown in FIG. 34 and a distributed constant line coupled by magnetic field coupling is shorter than a distributed constant line electrically coupled to a terminal.

FIG. 37 shows bandpass characteristics of a filter when each of the inductance of the inductor and the capacitance of the capacitor in FIG. 33 is smaller than the value for realizing the characteristics shown in FIG. 34 and the distributed constant line coupled by magnetic field coupling is longer than the distributed constant line electrically coupled to the terminal.

FIG. 38 is a perspective view illustrating structure of the filter in FIG. 33.

FIG. 39 is a graph showing bandpass characteristics of the filter in FIG. 38.

FIG. 40 is an equivalent circuit diagram of a filter according to Modification Example 1 of Embodiment 3.

FIG. 41 is an equivalent circuit diagram of a filter according to Modification Example 2 of Embodiment 3

FIG. 42 is an equivalent circuit diagram of a filter according to Modification Example 3 of Embodiment 3.

FIG. 43 is a perspective view illustrating structure of a filter according to Modification Example 4 of Embodiment 3.

FIG. 44 is a perspective view illustrating structure of a filter according to Modification Example 5 of Embodiment 3.

FIG. 45 is an equivalent circuit diagram of a filter according to Modification Example 6 of Embodiment 3.

FIG. 46 is a graph showing bandpass characteristics of the filter in FIG. 45.

FIG. 47 is an equivalent circuit diagram of a filter according to Modification Example 7 of Embodiment 3.

FIG. 48 is a graph showing bandpass characteristics of the filter in FIG. 47.

FIG. 49 is an equivalent circuit diagram of a filter according to Modification Example 8 of Embodiment 3.

FIG. 50 is a graph showing bandpass characteristics of the filter in FIG. 49.

FIG. 51 is an equivalent circuit diagram of a filter according to Modification Example 9 of Embodiment 3.

FIG. 52 is a graph showing bandpass characteristics of the filter in FIG. 51.

FIG. 53 is an equivalent circuit diagram of a filter according to Modification Example 10 of Embodiment 3.

FIG. 54 is a graph showing bandpass characteristics of the filter in FIG. 53.

FIG. 55 is an equivalent circuit diagram of a filter according to Modification Example 11 of Embodiment 3.

FIG. 56 is a block diagram of an antenna module according to Embodiment 4.

FIG. 57 is a graph showing bandpass characteristics of the antenna module in FIG. 56.

FIG. 58 is a diagram illustrating cross-sectional structure of an antenna module according to Embodiment 5.

FIG. 59 is an equivalent circuit diagram of a radiating element according to Embodiment 6.

FIG. 60 is a perspective view of structure of the radiating element in FIG. 59.

FIG. 61 is a plan view of the radiating element in FIG. 59 viewed in the Y-axis direction.

FIG. 62 is a graph showing reflection characteristics of the radiating element in FIG. 59 to FIG. 61.

### DESCRIPTION OF EMBODIMENTS

Hereinafter, embodiments will be described in detail with reference to the figures. Note that, in the figures, the same or corresponding parts are denoted by the same reference numerals, and description thereof will not be repeated in principle.

### Embodiment 1

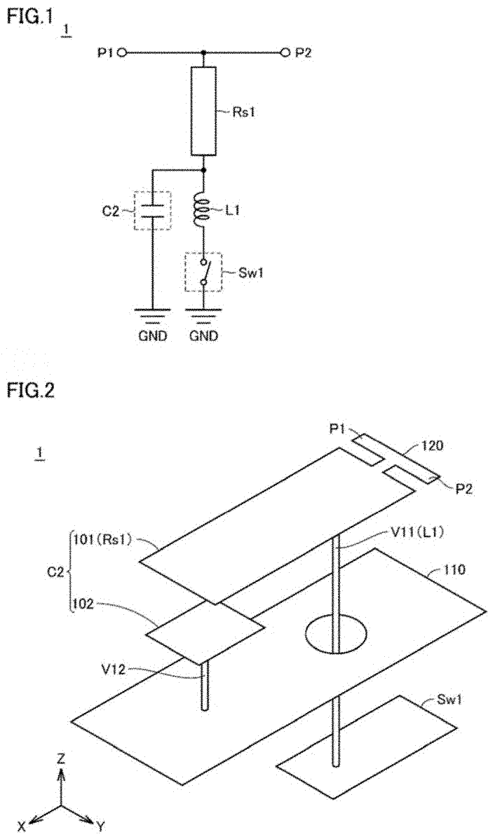

FIG. 1 is an equivalent circuit diagram of a filter 1 according to Embodiment 1. As illustrated in FIG. 1, the filter 1 includes a terminal P1 (first terminal), a terminal P2 (second terminal), a distributed constant line Rs1 (first distributed constant line), an inductor L1 (first impedance element), a capacitor C2 (second impedance element), and a switch Sw1 (first switch).

The distributed constant line Rs1 is connected to a signal path between the terminals P1 and P2. When a desired wavelength of a signal passing through the signal path is λ, a length of the distributed constant line Rs1 is 2/2 or λ/4. That is, the distributed constant line Rs1 functions as a λ/2 resonator or a λ/4 resonator. Note that, when a distributed constant line is formed of a dielectric, a length of the distributed constant line means an electrical length determined by an effective dielectric constant of the dielectric.

The inductor L1 and the switch Sw1 are connected in series in this order between the distributed constant line Rs1 and a ground point GND. The inductor L1 and the switch Sw1 may be connected in series in an order reverse to this order between the distributed constant line Rs1 and the ground point GND. The capacitor C2 is connected between the distributed constant line Rs1 and the ground point GND. Impedance of the switch Sw1 when the switch Sw1 is in a conductive state is inductive. The impedance of the switch Sw1 when the switch Sw1 is in a non-conductive state is capacitive.

Note that, a case where an impedance element is connected to the distributed constant line Rs1 includes a case where an impedance element is connected to one end of the distributed constant line Rs1 and a case where an impedance element is connected to a central part of the distributed constant line Rs1.

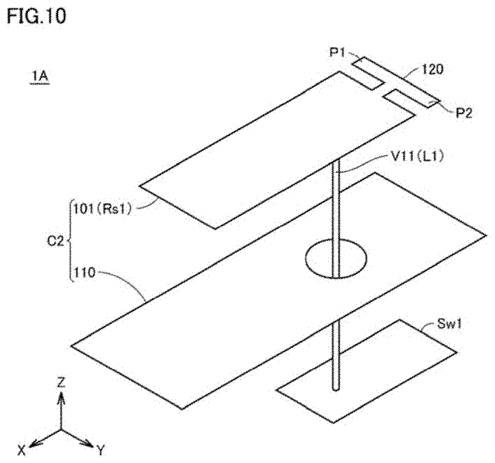

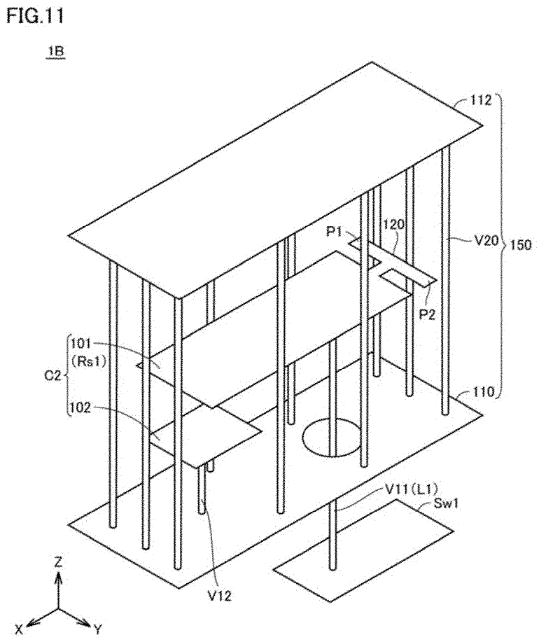

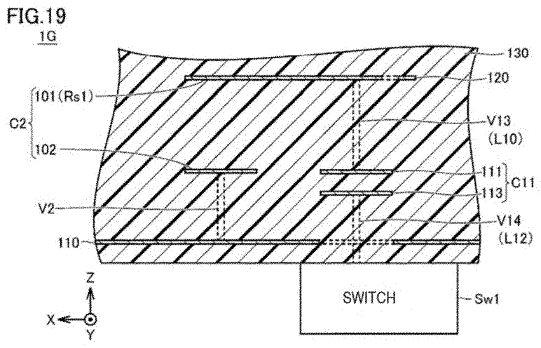

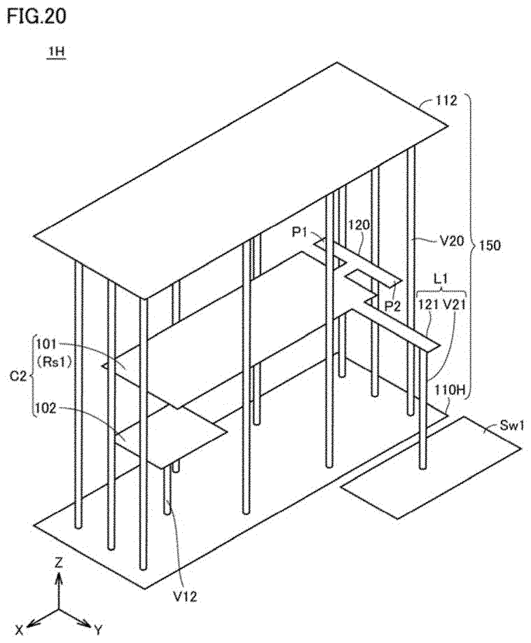

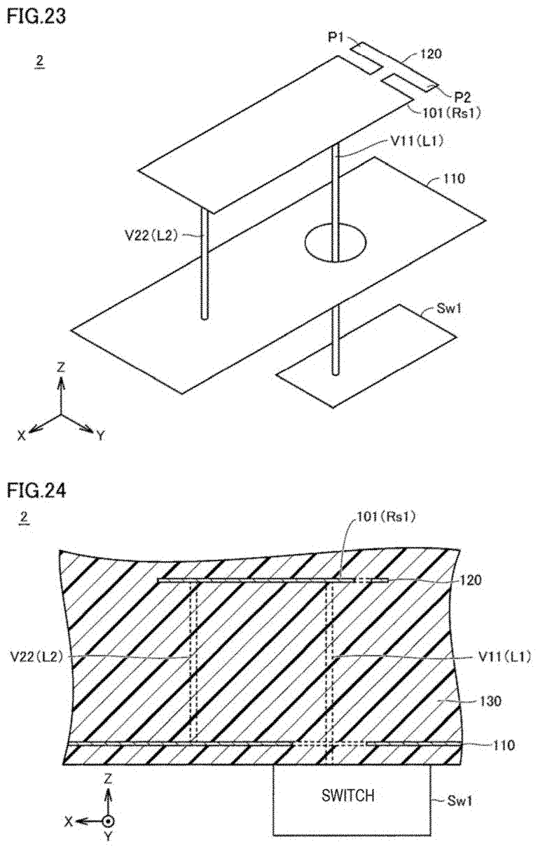

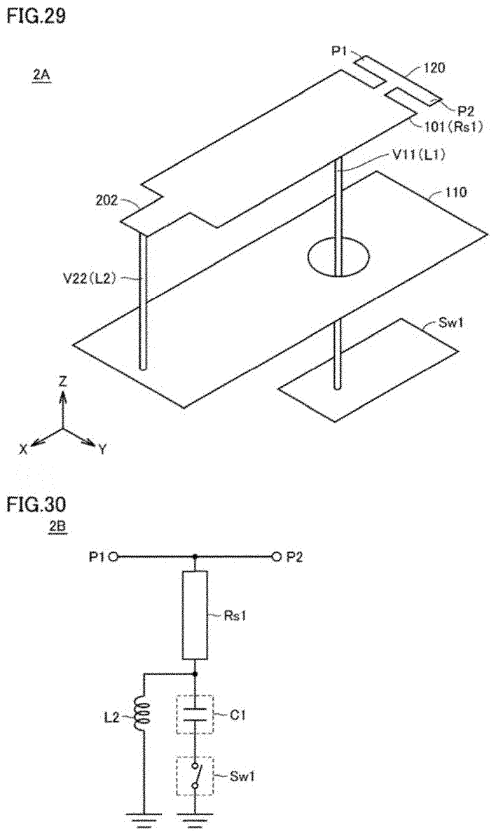

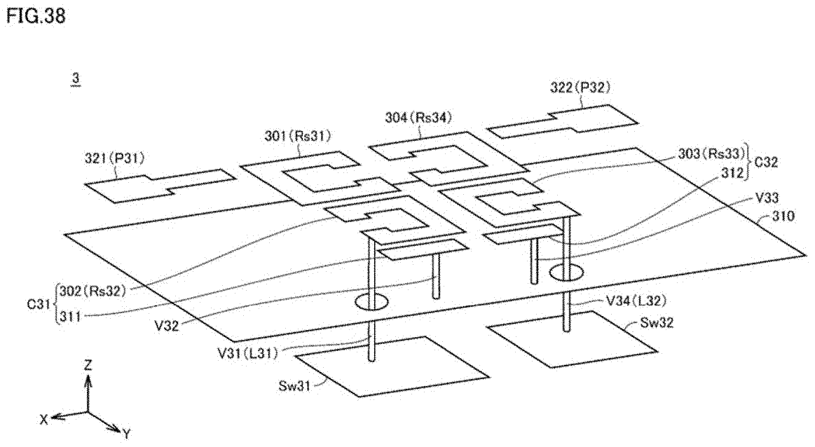

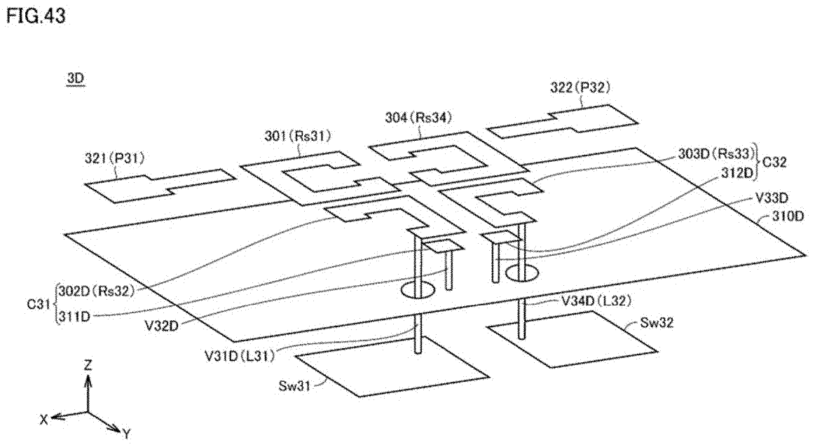

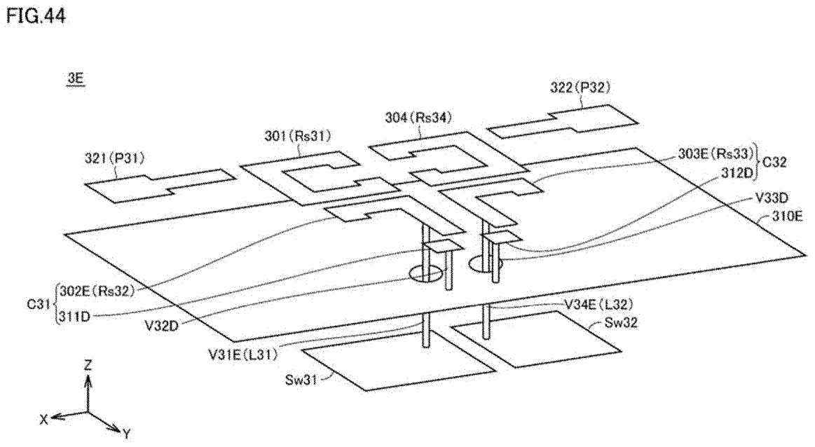

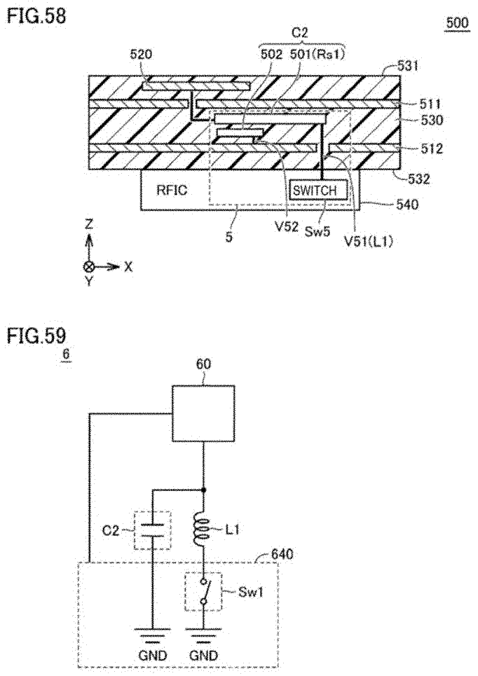

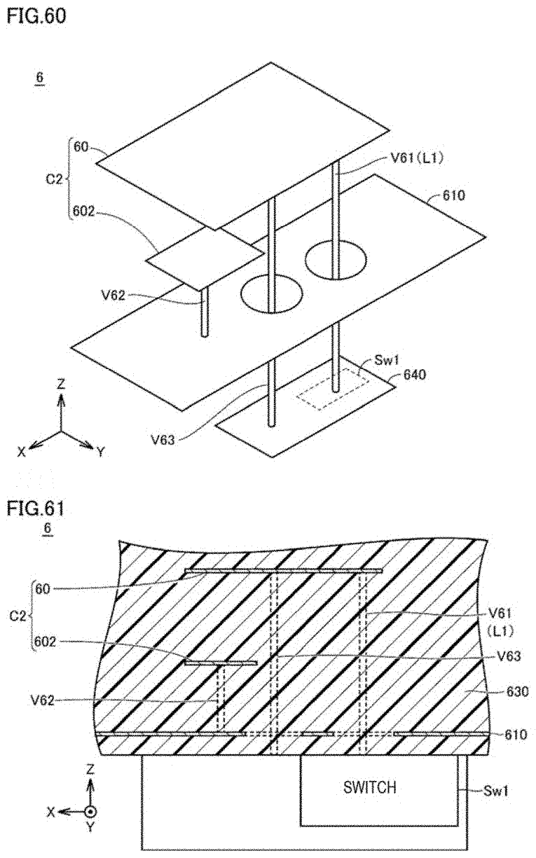

FIG. 2 is a perspective view of structure of the filter 1 in FIG. 1. FIG. 3 is a plan view of the filter 1 in FIG. 2 viewed in a Y-axis direction. In FIG. 2 and FIG. 3, an X-axis, a Y-axis, and a Z-axis are orthogonal to each other. The same applies to FIG. 10 to FIG. 16, FIG. 19, FIG. 20, FIG. 23, FIG. 24, FIG. 29, FIG. 32, FIG. 38, FIG. 43, FIG. 44, FIG. 58, FIG. 60, and FIG. 61.

As illustrated in FIGS. 2 and 3, the filter 1 includes line electrodes 101 and 120, a capacitor electrode 102, a ground electrode 110 (first ground electrode), a via conductor V11 (first via conductor), a via conductor V12, a dielectric substrate 130, and the switch Sw1. The line electrodes 101 and 120, the capacitor electrode 102, the ground electrode 110, the via conductors V11 and V12 are formed inside the dielectric substrate 130.

The line electrode 101 extends in a band shape in an X-axis direction and forms the distributed constant line Rs1. The line electrode 120 extends in the Y-axis direction. The line electrode 120 is connected to the line electrode 101. Both ends of the line electrode 120 form the terminals P1 and P2, respectively. The ground electrode 110 is disposed between the line electrode 101 and the switch Sw1. The ground electrode 110 and the switch Sw1 are connected to a ground terminal (not illustrated). The ground electrode 110 forms a ground point as a ground conductor portion. The via conductor V11 passes through the ground electrode 110 and connects the line electrode 101 and the switch Sw1. The via conductor V11 is insulated from the ground electrode 110. The via conductor V11 forms the inductor L1. The capacitor electrode 102 faces the line electrode 101 in a Z-axis direction. The via conductor V12 connects the capacitor electrode 102 and the ground electrode 110. The line electrode 101 and the capacitor electrode 102 form the capacitor C2.

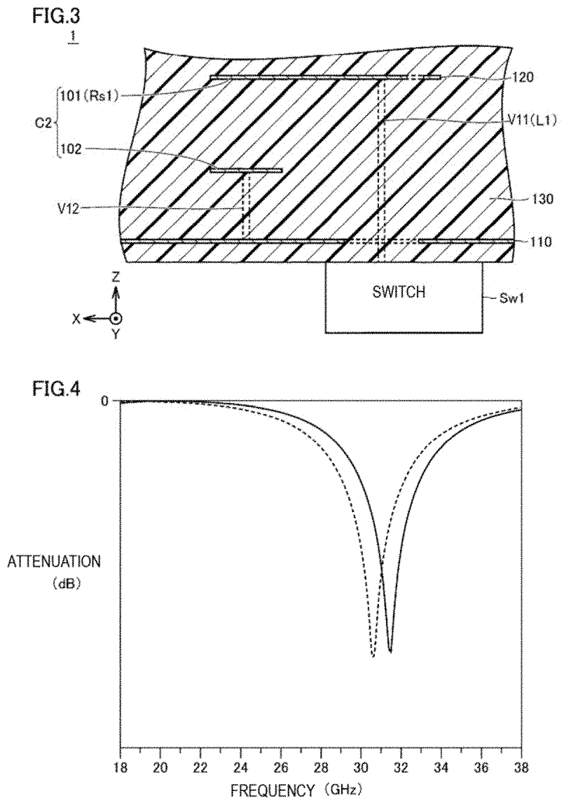

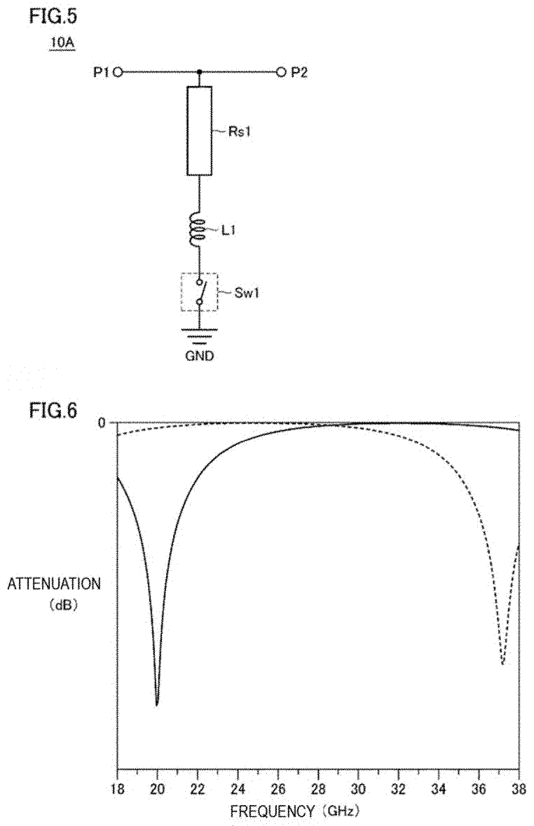

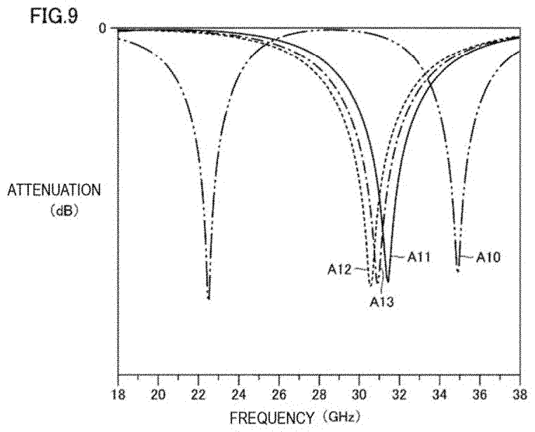

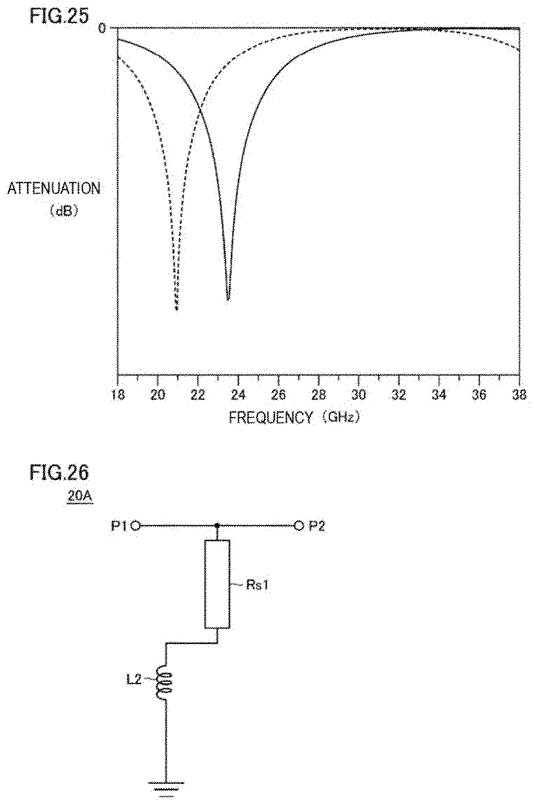

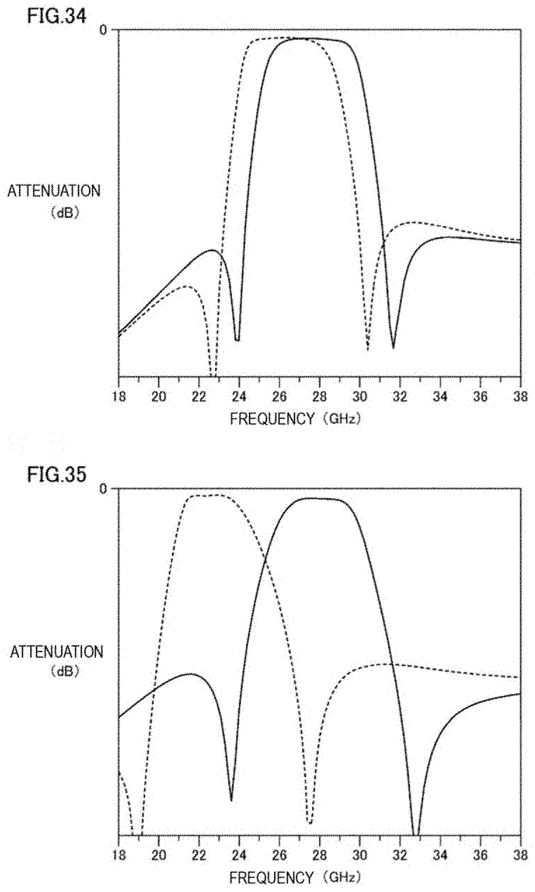

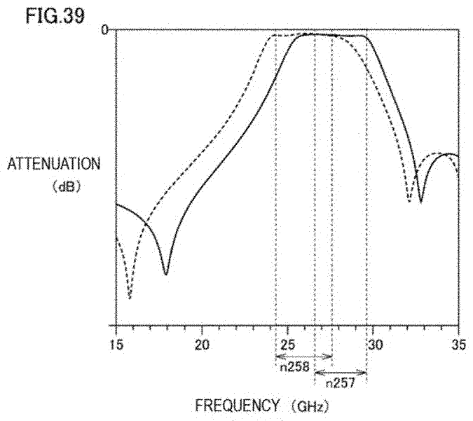

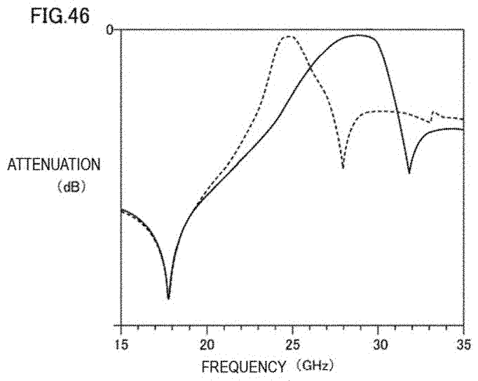

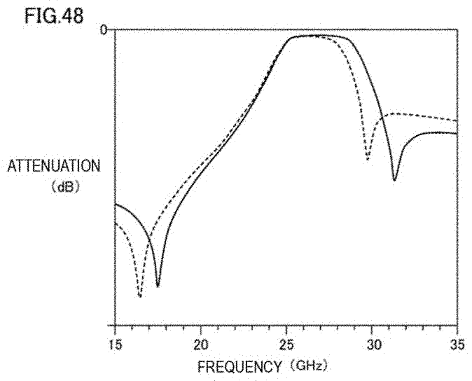

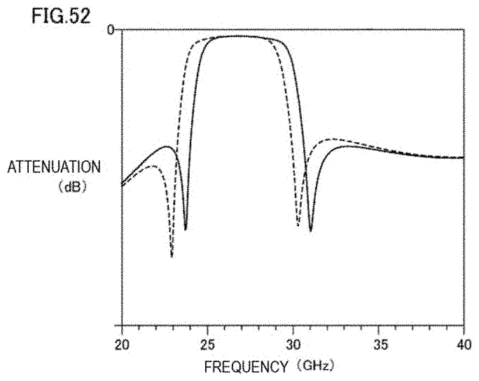

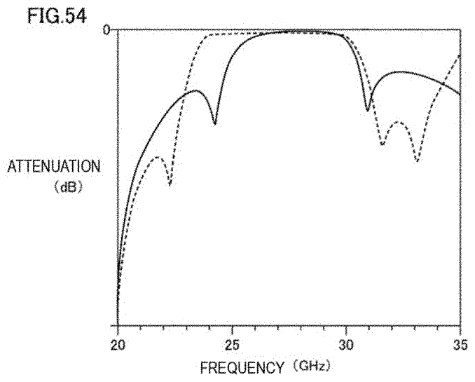

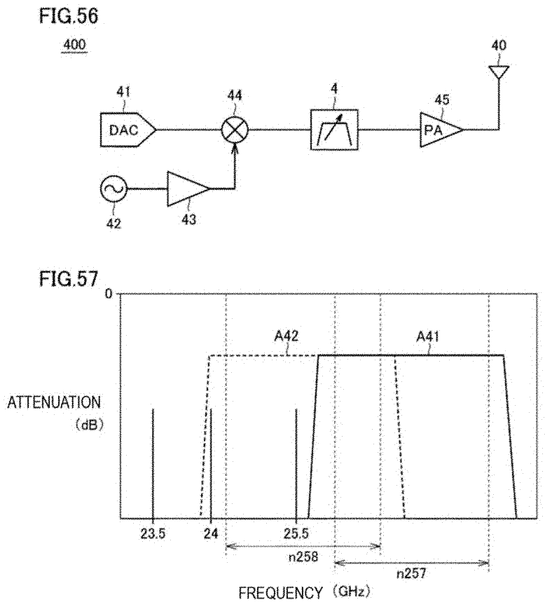

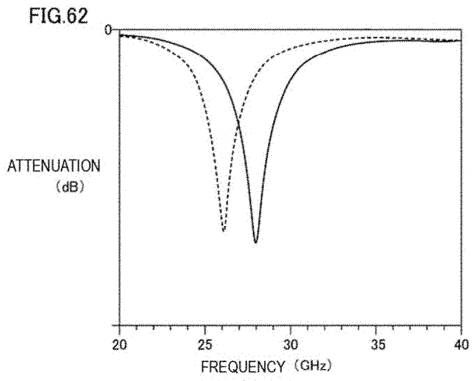

FIG. 4 is a graph showing bandpass characteristics of the filter 1 in FIG. 1. In FIG. 4, a solid line indicates bandpass characteristics of the filter 1 when the switch Sw1 in FIG. 1 is in the conductive state, and a dotted line indicates bandpass characteristics of the filter 1 when the switch Sw1 in FIG. 1 is in the non-conductive state. In FIG. 4, a distributed constant of the line electrode 120 in FIG. 2 is not taken into consideration. Attenuation in a vertical axis in FIG. 4 increases in a direction from the 0 dB toward a lower side. The same applies to FIG. 6, FIG. 9, FIG. 25, FIG. 28, FIG. 34 to FIG. 37, FIG. 39, FIG. 46, FIG. 48, FIG. 50, FIG. 52, FIG. 54, FIG. 57 and FIG. 62. Note that, bandpass characteristics of a filter are frequency characteristics of an insertion loss of the filter. The insertion loss is maximized at a frequency at which an attenuation pole appears.

As shown in FIG. 4, by switching the switch Sw1, the bandpass characteristics of the filter 1 can be changed. In the filter 1, by using a difference between impedance of the switch Sw1 in the conductive state and impedance of the switch Sw1 in the non-conductive state, the bandpass characteristics of the filter 1 can be adjusted without using a special configuration (for example, a variable capacitor) configured to be capable of changing impedance. According to the filter 1, a function of changing a pass band can be realized in a small design region, and at low cost.

FIG. 5 is an equivalent circuit diagram of a filter 10A according to Comparative Example 1. A configuration of the filter 10A is a configuration obtained by removing the capacitor C2 from the filter 1 in FIG. 1. Since the configurations are similar except for that, the description will not be repeated. FIG. 6 is a graph showing bandpass characteristics of the filter 10A in FIG. 5. In FIG. 6, a solid line indicates bandpass characteristics of the filter 10A when the switch Sw1 in FIG. 5 is in a conductive state, and a dotted line indicates bandpass characteristics of the filter 10A when the switch Sw1 in FIG. 5 is in a non-conductive state.

Comparing FIG. 4 and FIG. 6, an amount of change in a frequency of an attenuation pole due to the switching of the switch Sw1 is smaller in FIG. 4. That is, in the filter 1, an amount of change in a pass band due to the switching of the switch Sw1 can be reduced by the capacitor C2.

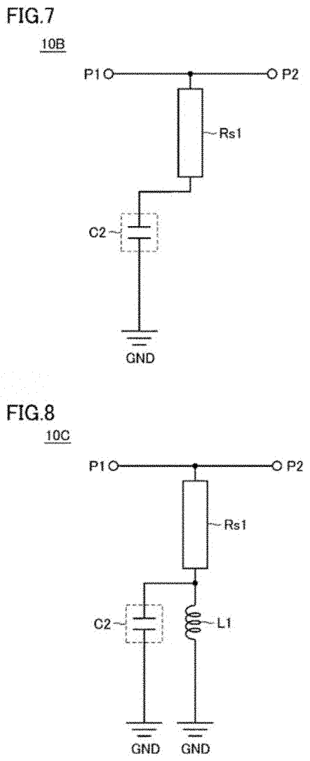

FIG. 7 is an equivalent circuit diagram of a filter 10B according to Comparative Example 2. A configuration of the filter 10B is a configuration obtained by removing the inductor L1 and the switch Sw1 from the filter 1 illustrated in FIG. 1. Since the configurations are similar except for these, the description will not be repeated. FIG. 8 is an equivalent circuit diagram of a filter 10C according to Comparative Example 3. A configuration of the filter 10C is a configuration obtained by removing the switch Sw1 from the filter 1 in FIG. 1. Since the configurations are similar except for this, the description will not be repeated.

FIG. 9 is a graph showing bandpass characteristics A11 and A12 of the filter 1 in FIG. 1, bandpass characteristics A13 of the filter 10B in FIG. 7, and bandpass characteristics A10 of the filter 10C in FIG. 8. In FIG. 9, the bandpass characteristics A11 indicate bandpass characteristics of the filter 1 when the switch Sw1 in FIG. 1 is in the conductive state, and the bandpass characteristics A12 indicate the bandpass characteristics of the filter 1 when the switch Sw1 in FIG. 1 is in the non-conductive state.

Referring to FIG. 1 and FIG. 8, the configuration of the filter 1 is a configuration in which the switch Sw1 is connected between the inductor L1 of the filter 10C and the ground point. As shown in FIG. 9, the bandpass characteristics A10 of the filter 10C are brought close to the bandpass characteristics A13 of the filter 10B by the switch Sw1. Due to the impedance of the switch Sw1, the bandpass characteristics A11 when the switch Sw1 is in the conductive state and the bandpass characteristics A12 when the switch Sw1 is in the non-conductive state deviate from the bandpass characteristics A13. That is, by switching the switch Sw1, the bandpass characteristics of the filter 1 can be switched between the bandpass characteristics A11 and A12.

The structure of the filter according to Embodiment 1 is not limited to the structure illustrated in FIG. 2. FIG. 10 is a perspective view of structure of a filter 1A according to Modification Example 1 of Embodiment 1. A configuration of the filter 1A is structure obtained by removing the capacitor electrode 102 and the via conductor V12 from the filter 1 in FIG. 2. Since the configurations are similar except for these, the description will not be repeated. As illustrated in FIG. 10, the line electrode 101 and the ground electrode 110 face each other in the Z-axis direction and form the capacitor C2.

In Embodiment 1, the case where the ground conductor portion is formed of one ground electrode has been described. Other conductors may be included in the ground conductor portion. FIG. 11 is a perspective view of structure of a filter 1B according to Modification Example 2 of Embodiment 1. A configuration of the filter 1B is a configuration in which a ground electrode 112 (second ground electrode) and a plurality of ground via conductors V20 are added to the filter 1 in FIG. 2. Since the configurations are similar except for these, the description will not be repeated.

As illustrated in FIG. 11, the ground electrode 112 faces the line electrode 101 on a side opposite to the ground electrode 110. The ground via conductors V20 are disposed so as to surround a line electrode 101. The ground via conductors V20 connect the ground electrodes 110 and 112. The ground electrodes 110 and 112 and the ground via conductors V20 form a ground conductor portion 150.

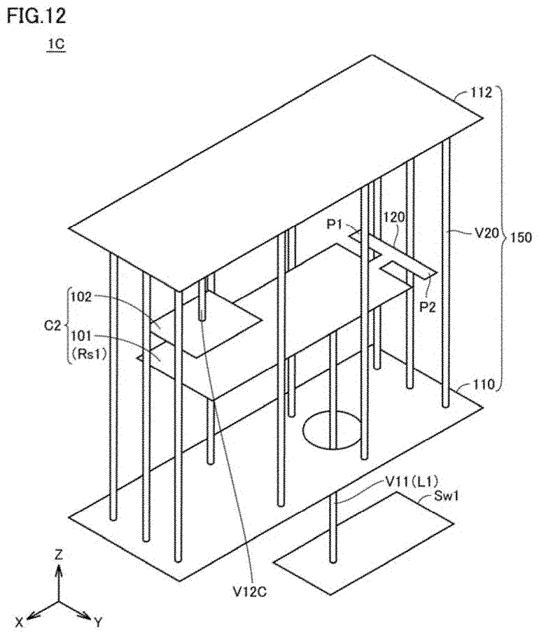

FIG. 12 is a perspective view of structure of a filter 1C according to Modification Example 3 of Embodiment 1. A configuration of the filter 1C is a configuration in which a position of the capacitor electrode 102 in FIG. 11 is changed and the via conductor V12 is replaced with a via conductor V12C. Since the configurations are similar except for these, the description will not be repeated.

As illustrated in FIG. 12, the capacitor electrode 102 is connected to the ground electrode 112 by the via conductor V12C. The capacitor electrode 102 faces the line electrode 101 between the line electrode 101 and the ground electrode 112.

In the filters 1B and 1C, since a periphery of the line electrode 101 is surrounded by the ground conductor portion 150, a shielding effect of the filters 1B and 1C is higher than that of the filter 1.

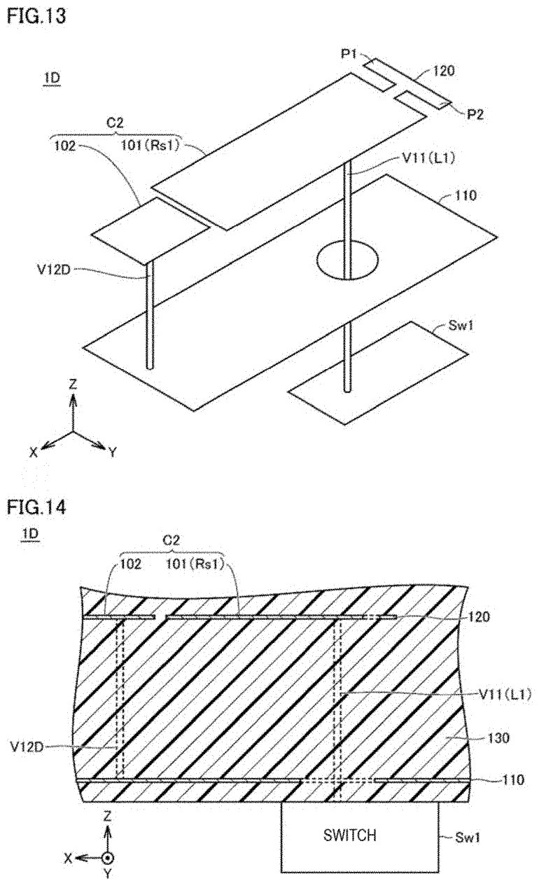

FIG. 13 is a perspective view of structure of a filter 1D according to Modification Example 4 of Embodiment 1. FIG. 14 is a plan view of the filter 1D in FIG. 13 viewed in the Y-axis direction. A configuration of the filter 1D is a configuration in which a position of the capacitor electrode 102 in FIG. 2 is changed, and the via conductor V12 is replaced with a via conductor V12D. Since the configurations are similar except for these, the description will not be repeated.

As illustrated in FIG. 13 and FIG. 14, the capacitor electrode 102 is formed at the same position as that of the line electrode 101 in the Z-axis direction. That is, a distance between the capacitor electrode 102 and the ground electrode 110 is equal to a distance between the line electrode 101 and the ground electrode 110. The capacitor electrode 102 is close to the line electrode 101 in the X-axis direction. The via conductor V12D connects the capacitor electrode 102 and the ground electrode 110. The line electrode 101 and the capacitor electrode 102 form the capacitor C2.

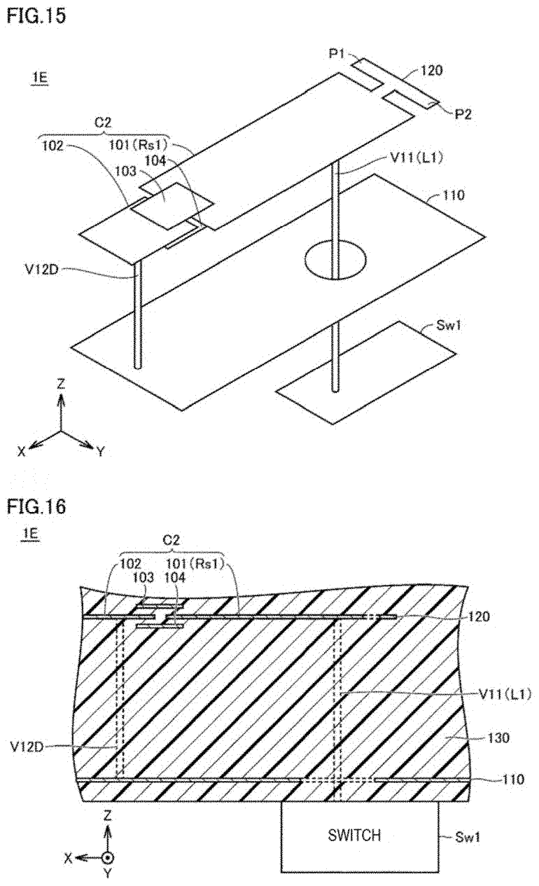

FIG. 15 is a perspective view of structure of a filter 1E according to Modification Example 5 of Embodiment 1. FIG. 16 is a plan view of the filter 1E in FIG. 15 viewed in the Y-axis direction. A configuration of the filter 1E is a configuration in which the capacitor electrode 104 (third capacitor electrode) and a capacitor electrode 103 (second capacitor electrode) are added to the filter 1D in FIG. 13 and FIG. 14. Since the configurations are similar except for these, the description will not be repeated.

As illustrated in FIG. 15 and FIG. 16, the capacitor electrode 103 faces each of the capacitor electrode 102 and the line electrode 101 on a side opposite to the ground electrode 110. A capacitor electrode 104 faces each of the capacitor electrode 102 and the line electrode 101 between the line electrode 101 and the ground electrode 110. The capacitor C2 is formed by the capacitor electrodes 103 and 104 in addition to the line electrode 101 and the capacitor electrode 102. Capacitance of the capacitor C2 of the filter 1E is larger than capacitance of the capacitor C2 of the filter 1D. By adding at least one of the capacitor electrodes 103 and 104, the capacitance of the capacitor C2 of the filter 1D can be increased. A length (width) in the Y-axis direction of each of the capacitor electrodes 103 and 104 may be equal to or larger than a width of the line electrode 101 or may be smaller than the width of the line electrode 101.

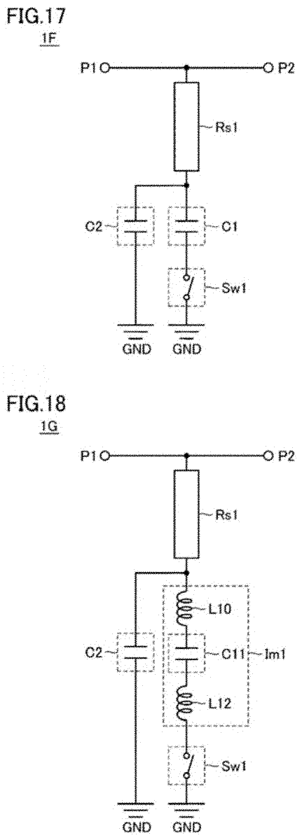

The impedance element connected between the distributed constant line Rs1 and the switch Sw1 in FIG. 1 may be a capacitor. FIG. 17 is an equivalent circuit diagram of a filter 1F according to Modification Example 6 of Embodiment 1. A configuration of the filter 1F is a configuration in which the inductor L1 in FIG. 1 is replaced with a capacitor C1 (first impedance element). Since the configurations are similar except for this, the description will not be repeated.

The first impedance element may include a plurality of circuit elements. FIG. 18 is an equivalent circuit diagram of a filter 1G according to Modification Example 7 of Embodiment 1. A configuration of the filter 1G is a configuration in which the inductor L1 in FIG. 1 is replaced with an impedance element Im1 (first impedance element). Since the configurations are similar except for this, the description will not be repeated.

As illustrated in FIG. 18, the impedance element Im1 includes inductors L10 and L12 and a capacitor C11. The inductor L10, the capacitor C11, and the inductor L12 are connected in series in this order between the distributed constant line Rs1 and the switch Sw1.

FIG. 19 is a plan view of structure of the filter 1G in FIG. 18 viewed in the Y-axis direction. The structure of the filter 1G is structure in which the via conductor V1 illustrated in FIG. 3 is replaced with via conductors V13 and V14 and capacitor electrodes 111 and 113. Since the configurations are similar except for these, the description will not be repeated.

As illustrated in FIG. 19, the via conductor V13 connects the line electrode 101 and the capacitor electrode 111. The via conductor V13 forms the inductor L10. The capacitor electrode 111 faces the capacitor electrode 113 in the Z-axis direction. The capacitor electrodes 111 and 113 form the capacitor C11. The via conductor V14 passes through the ground electrode 110 and connects the capacitor electrode 113 and the switch Sw1. The via conductor V14 is insulated from the ground electrode 110. The via conductor V14 forms the inductor L12.

An inductor included in an impedance element may include a line electrode. FIG. 20 is a perspective view of structure of a filter 1H according to Modification Example 8 of Embodiment 1. The structure of the filter 1H is structure in which the via conductor V11 is removed from the structure of the filter 1B in FIG. 11, the ground electrode 110 is replaced with a ground electrode 110H (first ground electrode), a line electrode 121 and a via conductor V21 are added, and a position of the switch Sw1 is changed. Since the configurations are similar except for these, the description will not be repeated.

As illustrated in FIG. 20, the line electrode 121 extends from the line electrode 101 in the Y-axis direction and passes between two of the via conductors V20. The via conductor V21 connects the line electrode 121 and the switch Sw1. The line electrode 121 and the via conductor V21 form the inductor L1.

In plan view of the filter 1H from the Y-axis direction, the switch Sw1 is disposed between the line electrode 101 and the ground electrode 110H. In plan view of the filter 1H from the Y-axis direction, the switch Sw1 may be disposed between the line electrode 101 and the ground electrode 112. In plan view of the filter 1H from the Y-axis direction, the ground electrode 110H may be disposed between the switch Sw1 and the line electrode 101, or the ground electrode 112 may be disposed between the switch Sw1 and the line electrode 101.

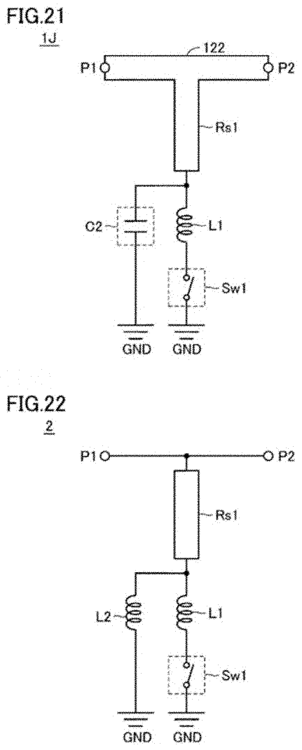

A distributed constant line may form a stub. FIG. 21 is an equivalent circuit diagram of a filter 1J according to Modification Example 9 of Embodiment 1. A configuration of the filter 1J is a configuration in which a path connecting the terminals P1 and P2 in the filter 1 in FIG. 1 is illustrated as a line electrode 122 (specific line electrode). Since the configurations are similar except for that, the description will not be repeated. As illustrated in FIG. 21, the distributed constant line Rs1 forms a stub that is formed so as to protrude from the line electrode 122. The stub is provided for the purpose of impedance matching of the filter 1J or adjustment of characteristics of the filter 1J.

As described above, according to the filter according to any one of Embodiment 1 and Modification Examples 1 to 9, it is possible to realize a reduction in size and cost of a filter capable of changing a pass band.

### Embodiment 2

In Embodiment 1, the case has been described where the second impedance element is the capacitor. In Embodiment 2, a case where a second impedance element is an inductor will be described.

FIG. 22 is an equivalent circuit diagram of a filter 2 according to Embodiment 2. A configuration of the filter 2 is a configuration in which the capacitor C2 in FIG. 1 is replaced with an inductor L2. Since the configurations are similar except for this, the description will not be repeated.

FIG. 23 is a perspective view of structure of the filter 2 in FIG. 22. FIG. 24 is a plan view of the filter 2 in FIG. 23 viewed in the Y-axis direction. The structure of the filter 2 is structure in which a via conductor V22 (second via conductor) is added to the filter 1A in FIG. 10. Since the configurations are similar except for this, the description will not be repeated. As illustrated in FIG. 23 and FIG. 24, the via conductor V22 connects the line electrode 101 and the ground electrode 110 to form the inductor L2.

FIG. 25 is a diagram showing bandpass characteristics of the filter 2 in FIG. 22. In FIG. 25, a solid line indicates bandpass characteristics of the filter 2 when the switch Sw1 in FIG. 22 is in a conductive state, and a dotted line indicates bandpass characteristics of the filter 2 when the switch Sw1 in FIG. 22 is in a non-conductive state. As shown in FIG. 25, by switching the switch Sw1, the bandpass characteristics of the filter 2 can be changed.

Comparing FIG. 25 and FIG. 6, an amount of change in a frequency at an attenuation pole when the switch Sw1 is switched is smaller in FIG. 25. That is, in the filter 2, an amount of change in a pass band due to the switching of the switch Sw1 can be reduced by the inductor L2.

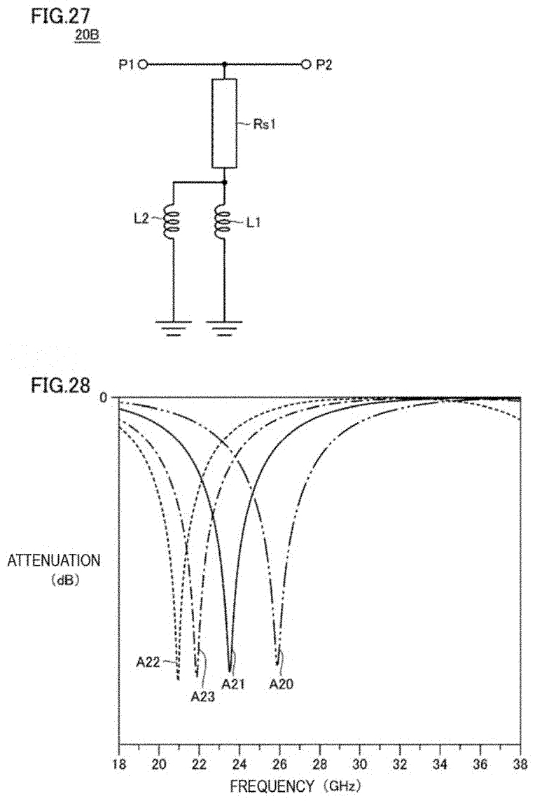

FIG. 26 is an equivalent circuit diagram of a filter 20A according to Comparative Example 4. A configuration of the filter 20A is a configuration obtained by removing the inductor L1 and the switch Sw1 from the filter 2 illustrated in FIG. 22. Since the configurations are similar except for these, the description will not be repeated. FIG. 27 is an equivalent circuit diagram of a filter 20B according to Comparative Example 5. A configuration of the filter 20B is a configuration obtained by removing the switch Sw1 from the filter 2 in FIG. 22. Since the configurations are similar except for this, the description will not be repeated.

FIG. 28 is a diagram showing bandpass characteristics A21 and A22 of the filter 2 in FIG. 22, bandpass characteristics A23 of the filter 20A in FIG. 26, and bandpass characteristics A20 of the filter 20B in FIG. 27. In FIG. 28, the bandpass characteristics A21 indicate bandpass characteristics of the filter 2 when the switch Sw1 in FIG. 22 is in a conductive state, and the bandpass characteristics A22 indicate bandpass characteristics of the filter 2 when the switch Sw1 in FIG. 22 is in a non-conductive state.

Referring to FIG. 22 and FIG. 27, the configuration of the filter 2 is a configuration in which switch Sw1 is connected between the inductor L1 of filter 20B and a ground point. As shown in FIG. 28, the bandpass characteristics A20 of the filter 20B are brought close to the bandpass characteristics A23 of the filter 20A by the switch Sw1. Due to impedance of the switch Sw1, the bandpass characteristics A21 when the switch Sw1 is in the conductive state and the bandpass characteristics A22 when the switch Sw1 is in the non-conductive state deviate from the bandpass characteristics A23. That is, by switching the switch Sw1, the bandpass characteristics of the filter 2 can be switched between the bandpass characteristics A21 and A22.

The structure of the filter according to Embodiment 2 is not limited to the structure illustrated in FIG. 23. FIG. 29 is a perspective view of structure of a filter 2A according to Modification Example 1 of Embodiment 2. The structure of the filter 2A is a configuration in which a line electrode 202 is added to the filter 2 in FIG. 23. Since the configurations are similar except for those, the description will not be repeated. As illustrated in FIG. 29, the line electrode 202 is connected to the line electrode 101. The via conductor V22 connects the line electrode 202 and the ground electrode 110.

The impedance element connected between the distributed constant line Rs1 and the switch Sw1 in FIG. 22 may be a capacitor. FIG. 30 is an equivalent circuit diagram of a filter 2B according to Modification Example 2 of Embodiment 2. A configuration of the filter 2B is a configuration in which the inductor L1 in FIG. 22 is replaced with the capacitor C1 (first impedance element). Since the configurations are similar except for this, the description will not be repeated.

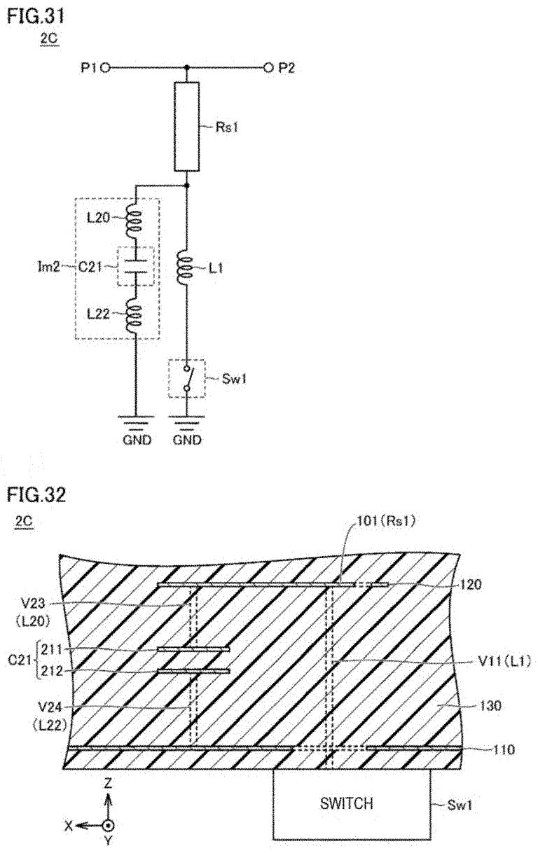

A second impedance element may include a plurality of circuit elements. FIG. 31 is an equivalent circuit diagram of a filter 2C according to Modification Example 3 of Embodiment 2. A configuration of the filter 2C is a configuration in which the inductor L2 in FIG. 22 is replaced with an impedance element Im2 (second impedance element). Since the configurations are similar except for this, the description will not be repeated.

As illustrated in FIG. 31, the impedance element Im2 includes inductors L20 and L22 and a capacitor C21. The inductor L20, the capacitor C21, and the inductor L22 are connected in series in this order between the distributed constant line Rs1 and a ground point.

FIG. 32 is a plan view of structure of the filter 2C in FIG. 31 viewed in the Y-axis direction. The structure of the filter 2C is structure in which the via conductor V22 in FIG. 24 is replaced with via conductors V23 and V24 and capacitor electrodes 211 and 212. Since the configurations are similar except for these, the description will not be repeated.

As illustrated in FIG. 32, the via conductor V23 connects the line electrode 101 and the capacitor electrode 211. The via conductor V23 forms the inductor L20. The capacitor electrode 211 faces the capacitor electrode 212 in the Z-axis direction. The capacitor electrodes 211 and 212 form the capacitor C21. The via conductor V24 connects the capacitor electrode 212 and the ground electrode 110. The via conductor V24 forms the inductor L22.

As described above, according to the filter according to any one of Embodiment 2 and Modification Examples 1 to 3 it is possible to realize a reduction in size and cost of a filter capable of changing a pass band.

### Embodiment 3

In each of Embodiments 1 and 2, the filter including one distributed constant line as a resonator has been described. The filter according to the embodiment may include a plurality of distributed constant lines as resonators. In Embodiment 3, a filter including four distributed constant lines as resonators will be described.

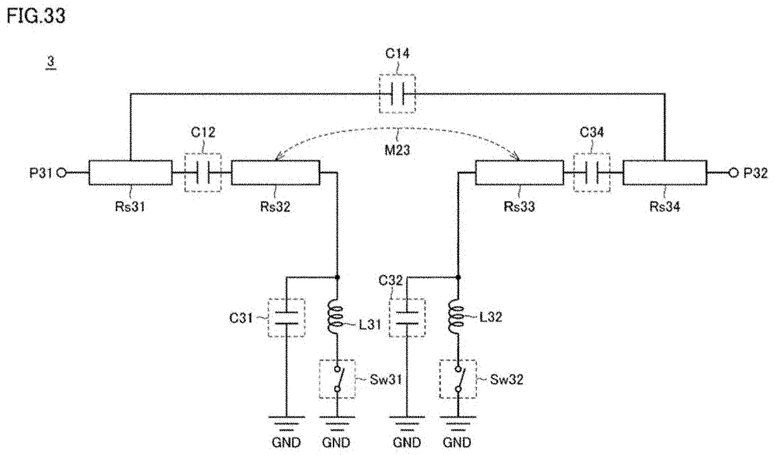

FIG. 33 is an equivalent circuit diagram of a filter 3 according to Embodiment 3. As illustrated in FIG. 33, the filter 3 includes a terminal P31 (first terminal), a terminal P32 (second terminal), a distributed constant line Rs31 (third distributed constant line), a distributed constant line Rs32 (first distributed constant line), a distributed constant line Rs33 (second distributed constant line), a distributed constant line Rs34 (fourth distributed constant line), an inductor L31 (first impedance element), an inductor L32 (third impedance element), a capacitor C31 (second impedance element), a capacitor C32 (fourth impedance element), a switch Sw31 (first switch), and a switch Sw32 (second switch).

The distributed constant line Rs31 is electrically connected to the terminal P31. That is, the distributed constant line Rs31 may be directly connected to the terminal P31 or may be electrically coupled to the terminal P31. The distributed constant line Rs34 is electrically connected to the terminal P32. That is, the distributed constant line Rs34 may be directly connected to the terminal P32 or may be electrically coupled to the terminal P32. Note that, a case where two circuit elements are electrically connected to each other includes a case where the two circuit elements are directly connected to each other and a case where the two circuit elements are electrically coupled (capacitively coupled) to each other.

The distributed constant line Rs31 is electrically coupled to the distributed constant line Rs32. In FIG. 33, a capacitor C12 connected between the distributed constant lines Rs31 and Rs32 represents electric field coupling between the distributed constant lines Rs31 and Rs32. A capacitor C14 connected between the distributed constant lines Rs31 and Rs34 represents electric field coupling between the distributed constant lines Rs31 and Rs34. A capacitor C34 connected between the distributed constant lines Rs33 and Rs34 represents electric field coupling between the distributed constant lines Rs33 and Rs34. The distributed constant line Rs32 is magnetically coupled to the distributed constant line Rs33. The magnetic field coupling between the distributed constant lines Rs32 and Rs33 is represented as M23.

Between the terminals P31 and P32, a signal path is formed by the distributed constant line Rs31, the capacitor C12, the distributed constant line Rs32, the magnetic field coupling M23, the distributed constant line Rs33, the capacitor C34, and the distributed constant line Rs34. In addition, between the terminals P31 and P32, another signal path is formed by the distributed constant line Rs31, the capacitor C14, and the distributed constant line Rs34.

When a desired wavelength of a signal passing through the signal path formed between the terminals P31 and P32 is λ, a length of the distributed constant line Rs31 is λ/2 or λ/4. That is, the distributed constant line Rs31 functions as a λ/2 resonator or a λ/4 resonator. The same applies to the distributed constant lines Rs32 to Rs34.

The inductor L31 and the switch Sw31 are connected in series in this order between one of both end portions of the distributed constant line Rs32, which is not connected to the capacitor C12, and the ground point GND. The capacitor C31 is connected between the one of the both end portions of the distributed constant line Rs32, which is not connected to the capacitor C12, and the ground point GND.

The inductor L32 and the switch Sw32 are connected in series in this order between an end portion of the distributed constant line Rs33 and the ground point GND. The capacitor C32 is connected between the end portion of the distributed constant line Rs33 and the ground point GND.

In the distributed constant lines Rs32 and Rs33 magnetically coupled to each other, intensity of the magnetic field is strongest at a central part of each of the distributed constant lines Rs32 and Rs33 and weakest at both end portions thereof. Thus, by connecting an impedance element to an end portion of each of the distributed constant lines Rs32 and Rs33, it is possible to reduce influence of the impedance element on a coupling state between the distributed constant lines Rs32 and Rs33. As a result, also when a conductive state and a non-conductive state of the switches Sw31 and Sw32 are switched, the coupling state between the distributed constant lines Rs32 and Rs33 is maintained, and thus a pass band width of the filter 3 can be maintained.

The length of the distributed constant line Rs31 is equal to a length of the distributed constant line Rs34. A length of the distributed constant line Rs32 is equal to a length of the distributed constant line Rs33. An inductance of the inductor L31 is equal to an inductance of the inductor L32. Capacitance of the capacitor C31 is equal to capacitance of the capacitor C32.

FIG. 34 is a diagram showing bandpass characteristics of the filter 3 in FIG. 33. In FIG. 34, a solid line indicates bandpass characteristics of the filter 3 when the switches Sw31 and Sw32 in FIG. 33 are in the conductive state, and a dotted line indicates bandpass characteristics of the filter 3 when the switches Sw31 and Sw32 in FIG. 33 are in the non-conductive state. As shown in FIG. 34, by switching the switches Sw31 and Sw32, the bandpass characteristics of the filter 3 can be changed while maintaining the pass band width.

FIG. 35 is a diagram showing bandpass characteristics of the filter 3 in FIG. 33 when the capacitance of the capacitors C31 and C32 in FIG. 33 is reduced as compared with the case in FIG. 34. In FIG. 35, a solid line indicates bandpass characteristics of the filter 3 when the switches Sw31 and Sw32 in FIG. 33 are in the conductive state, and a dotted line indicates bandpass characteristics of the filter 3 when the switches Sw31 and Sw32 in FIG. 33 are in the non-conductive state. As shown in FIG. 34 and FIG. 35, the bandpass characteristics of the filter 3 can be adjusted by changing the capacitance of the capacitors C31 and C32 in FIG. 33.

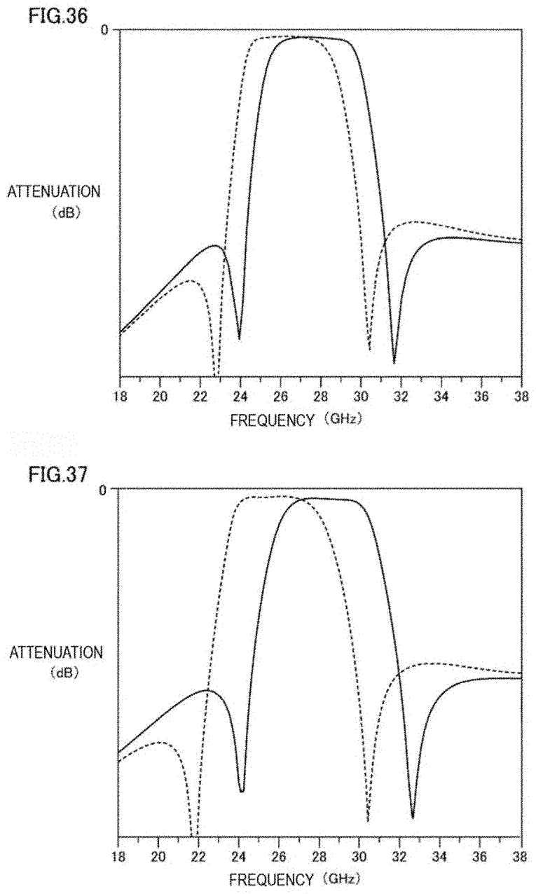

FIG. 36 shows bandpass characteristics of the filter 3 when each of the inductances of the respective inductors L31 and L32 and the capacitance of the capacitors C31 and C32 in FIG. 33 is larger than a value for realizing the characteristics shown in FIG. 34 and a length of each of the distributed constant lines Rs32 and Rs33 magnetically coupled to each other is shorter than a length of each of the distributed constant lines Rs31 and Rs34 electrically coupled to the terminals P1 and P3, respectively. In FIG. 36, a solid line indicates bandpass characteristics of the filter 3 when the switches Sw31 and Sw32 in FIG. 33 are in the conductive state, and a dotted line indicates bandpass characteristics of the filter 3 when the switches Sw31 and Sw32 in FIG. 33 are in the non-conductive state. The same applies to FIG. 37.

When FIG. 36 is compared with FIG. 34, both show substantially the same characteristics. By adjusting each of the inductances of the respective inductors L31 and L32 and the capacitance of the capacitors C31 and C32, the bandpass characteristics can be maintained also when the distributed constant lines Rs32 and Rs33 are shortened. That is, it is possible to reduce a size of the filter 3 while maintaining the bandpass characteristics of the filter 3.

FIG. 37 shows bandpass characteristics of the filter 3 when each of the inductances of the respective inductors L31 and L32 and the capacitance of the capacitors C31 and C32 in FIG. 33 is smaller than the value for realizing the characteristics shown in FIG. 34, and the length of each of the distributed constant lines Rs32 and Rs33 magnetically coupled to each other is longer than the length of each of the distributed constant lines Rs31 and Rs34 electrically coupled to the terminals P31 and P32, respectively.

When FIG. 37 is compared with FIG. 34, both show substantially the same characteristics. By lengthening the distributed constant lines Rs32 and Rs33, the bandpass characteristics can be maintained also when each of the inductances of the respective inductors L31 and L32 and the capacitance of the capacitors C31 and C32 is shortened. That is, it is possible to reduce a size of the filter 3 while maintaining the bandpass characteristics of the filter 3.

FIG. 38 is a perspective view illustrating structure of the filter 3 in FIG. 33. As illustrated in FIG. 38, the filter 3 includes line electrodes 301 to 304, a capacitor electrode 311 (first capacitor electrode), a capacitor electrode 312 (second capacitor electrode), a ground electrode 310, a via conductor V31 (first via conductor), via conductors V32 and V33, a via conductor V34 (second via conductor), terminal electrodes 321 and 322, and switches Sw31 and Sw32.

The line electrodes 301 to 304 each have a band shape and form the distributed constant lines Rs31 to Rs34, respectively. Each of the line electrodes 301 to 304 is wound around a central axis (not illustrated) extending in the Z-axis direction and is formed in a U-shape. An opening of the line electrode 301 and an opening of the line electrode 304 are adjacent to each other in the X-axis direction. Both ends of the line electrode 301 and both ends of the line electrode 304 are electrically coupled to each other. A central part of the line electrode 302 and a central part of the line electrode 303 are adjacent to each other in the X-axis direction and are magnetically coupled to each other. The line electrodes 301 and 302 are adjacent to each other in the Y-axis direction and are electrically coupled to each other. The line electrodes 303 and 304 are adjacent to each other in the Y-axis direction and are electrically coupled to each other.

The terminal electrodes 321 and 322 form the terminals P31 and P32, respectively. The terminal electrode 321 is adjacent to the line electrode 301 in the X-axis direction and electrically coupled thereto. The terminal electrode 322 is electrically coupled to the line electrode 304 in the X-axis direction.

The ground electrode 310 is disposed between the line electrodes 301 to 304 and the switches Sw31 and Sw32. The ground electrode 310 and the switches Sw31 and Sw32 are connected to a ground terminal (not illustrated). The ground electrode 310 forms a ground point.

The via conductor V31 passes through the ground electrode 310 and connects the line electrode 302 and the switch Sw31. The via conductor V31 is insulated from the ground electrode 310. The via conductor V31 forms the inductor L31. The capacitor electrode 311 faces the line electrode 302 in the Z-axis direction. The via conductor V32 connects the capacitor electrode 311 and the ground electrode 310. The line electrode 302 and the capacitor electrode 311 form the capacitor C31.

The via conductor V34 passes through the ground electrode 310 and connects the line electrode 303 and the switch Sw32. The via conductor V34 is insulated from the ground electrode 310. The via conductor V34 forms the inductor L32. The capacitor electrode 312 faces the line electrode 303 in the Z-axis direction. The via conductor V33 connects the capacitor electrode 312 and the ground electrode 310. The line electrode 303 and the capacitor electrode 312 form the capacitor C32.

Note that, although each of the line electrodes 301 to 304 illustrated in FIG. 38 functions as a resonator, when one end of the line electrode is grounded, the line electrode may function as a λ/4 resonator. In addition, each of the inductances of the respective inductors L31 and L32 and the capacitance of the capacitors C31 and C32 is adjusted so that each of the line electrodes 302 and 303 can be made shorter than each of the line electrodes 301 and 304.

FIG. 39 is a diagram showing bandpass characteristics of the filter 3 in FIG. 38. In FIG. 39, a solid line indicates bandpass characteristics of the filter 3 when the switches Sw31 and Sw32 in FIG. 38 are in a conductive state, and a dotted line indicates bandpass characteristics of the filter 3 when the switches Sw31 and Sw32 in FIG. 38 are in a non-conductive state. A frequency band n258 is a frequency band from 24.25 GHz to 27.5 GHz. A frequency band n257 is a frequency band from 26.5 GHz to 29.5 GHz. The frequency bands n257 and n258 are millimeter wave frequency bands. The same applies to the frequency bands n257 and n258 in FIG. 57.

As shown in FIG. 39, when the switches Sw31 and Sw32 in FIG. 38 are switched to the conductive state, the filter 3 can function as a filter that passes a signal included in the frequency band n257. When the switches Sw31 and Sw32 in FIG. 38 are switched to the non-conductive state, the filter 3 can function as a filter that passes a signal included in the frequency band n258.

In the filter 3, the case has been described where the pass band width of the filter 3 is maintained by connecting the impedance element to the end portion of each of the distributed constant lines Rs32 and Rs33 magnetically coupled to each other. The pass band width of the filter can be maintained also when an impedance element is connected to a central part of distributed constant lines Rs3l and Rs34 electrically coupled to each other.

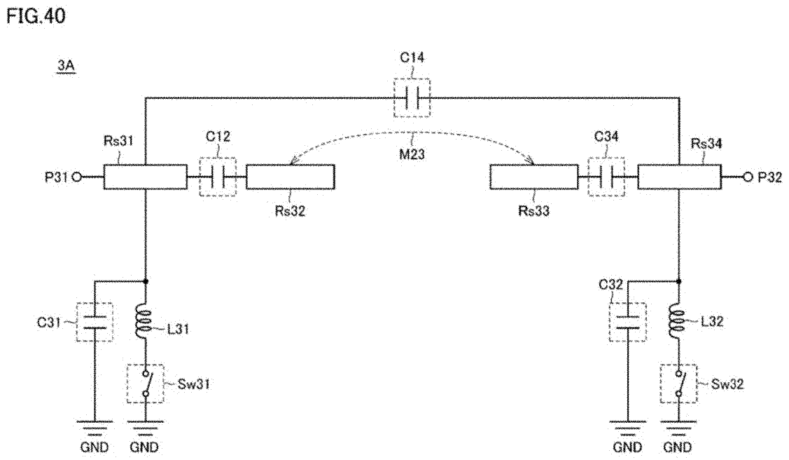

FIG. 40 is an equivalent circuit diagram of a filter 3A according to Modification Example 1 of Embodiment 3. A configuration of the filter 3A is a configuration in which a part to which the inductor L31 and the capacitor C31 in FIG. 33 are connected is changed from the end portion of the distributed constant line Rs32 to a central part of the distributed constant line Rs31 and a part to which the inductor L32 and the capacitor C32 in FIG. 33 are connected is changed from the end portion of the distributed constant line Rs33 to a central part of the distributed constant line Rs34. In the filter 3A, the distributed constant lines Rs31 and Rs34 correspond to a first distributed constant line and a second distributed constant line, respectively, and the distributed constant lines Rs32 and Rs33 correspond to a third partial constant line and a fourth distributed constant line, respectively. Since the configurations are similar except for these, the description will not be repeated.

In each of the distributed constant lines Rs31 and Rs34 electrically coupled to each other, intensity of the electric field is strongest at both end portions of each of the distributed constant lines Rs31 and Rs34 and weakest at a central part. Thus, by connecting an impedance element to the central part of each of the distributed constant lines Rs31 and Rs34, it is possible to reduce influence of the impedance element on a coupling state between the distributed constant lines Rs3l and Rs34. As a result, also when a conductive state and a non-conductive state of the switches Sw31 and Sw32 are switched, the coupling state between the distributed constant lines Rs3l and Rs34 is maintained, and thus a pass band width of the filter 3A can be maintained.

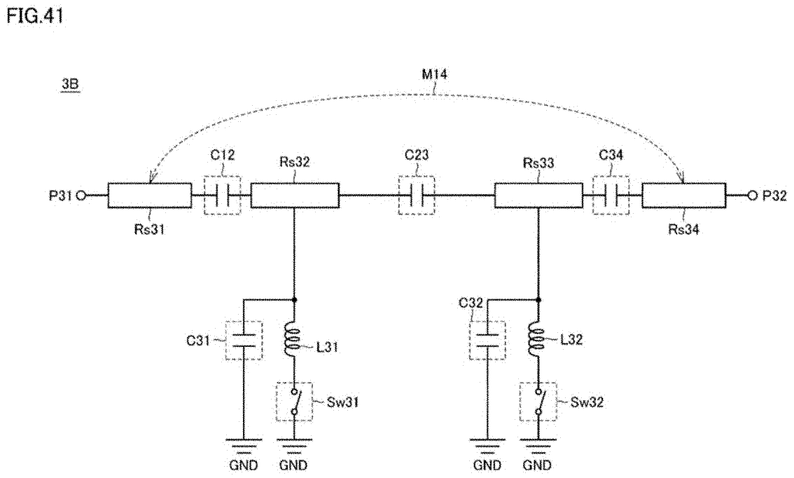

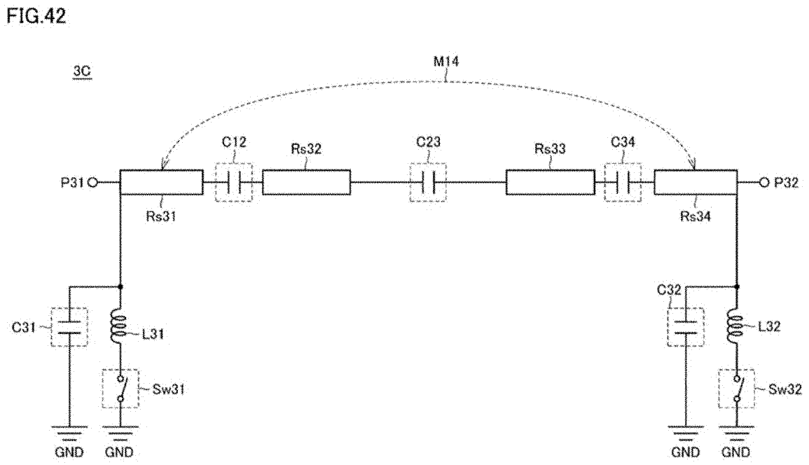

In the filters 3 and 3A, the case has been described in which the distributed constant lines Rs31 and Rs34 electrically connected to the terminals P31 and P32, respectively, are electrically coupled to each other and the distributed constant lines Rs32 and Rs33 not electrically connected to the terminals P31 and P32 are magnetically coupled to each other. In the following, by using FIG. 41 and FIG. 42, a case will be described where the distributed constant lines Rs31 and Rs34 are magnetically coupled to each other and the distributed constant lines Rs32 and Rs33 are electrically coupled to each other.

FIG. 41 is an equivalent circuit diagram of a filter 3B according to Modification Example 2 of Embodiment 3. In the filter 3B, the electric field coupling represented by the capacitor C14 between the distributed constant lines Rs31 and Rs34 in FIG. 33 is replaced with magnetic field coupling M14, and the magnetic field coupling M23 between the distributed constant lines Rs32 and Rs33 is replaced with electric field coupling represented by a capacitor C23. In the filter 3B, the part to which the inductor L31 and the capacitor C31 in FIG. 33 are connected is changed from the end portion of the distributed constant line Rs32 to a central part of the distributed constant line Rs32, and the part to which the inductor L32 and the capacitor C32 in FIG. 33 are connected is changed from the end portion of the distributed constant line Rs33 to a central part of the distributed constant line Rs33. In the filter 3B, similar to the filter 3, the distributed constant lines Rs32 and Rs33 correspond to a first partial constant line and a second distributed constant line, respectively, and the distributed constant lines Rs31 and Rs34 correspond to a third partial constant line and a fourth distributed constant line, respectively. Since the configurations are similar except for these, the description will not be repeated.

FIG. 42 is an equivalent circuit diagram of a filter 3C according to Modification Example 3 of Embodiment 3. A configuration of the filter 3C is a configuration in which the part to which the inductor L31 and the capacitor C31 in FIG. 41 are connected is changed from the central part of the distributed constant line Rs32 to an end portion of the distributed constant line Rs31 and the part to which the inductor L32 and the capacitor C32 in FIG. 41 are connected is changed from the central part of the distributed constant line Rs33 to an end portion of the distributed constant line Rs34. In the filter 3C, similar to the filter 3A, the distributed constant lines Rs31 and Rs34 correspond to a first partial constant line and a second distributed constant line, respectively, and the distributed constant lines Rs32 and Rs33 correspond to a third partial constant line and a fourth distributed constant line, respectively. Since the configurations are similar except for these, the description will not be repeated.

A shape of a line electrode forming a distributed constant line may be a shape other than a U-shape. In a certain distributed constant line, by shortening a length of a part that is not adjacent to another distributed constant line, while shortening the length of the distributed constant line, it is possible to maintain a length of a part adjacent to the other distributed constant line. As a result, while a length of a distributed constant line is shortened to adjust a resonant frequency of the distributed constant line, it is possible to maintain coupling between the distributed ordinal line and another distributed constant line.

FIG. 43 is a perspective view of structure of a filter 3D according to Modification Example 4 of Embodiment 3. The structure of the filter 3D is a configuration in which the line electrodes 302 and 303, the ground electrode 310, the capacitor electrodes 311 and 312, and the via conductors 731 to 734 in FIG. 38 are replaced with line electrodes 302D and 303D, a ground electrode 310D, a capacitor electrode 311D (first capacitor electrode), a capacitor electrode 312D (second capacitor electrode), and via conductors V31D, V32D, V33D, and V34D, respectively. Since the configurations are similar except for these, the description will not be repeated.

As illustrated in FIG. 43, the line electrodes 302D and 303D each have a band shape and form the distributed constant lines Rs32 and Rs33, respectively. Each of the line electrodes 302D and 303D is wound around a central axis (not illustrated) extending in the Z-axis direction. In comparison with the line electrode 302 in FIG. 38, a length of a part of the line electrode 302D that is not adjacent to the line electrodes 301 and 303D is shortened. In comparison with the line electrode 303 in FIG. 38, a part of the line electrode 303D that is not adjacent to the line electrodes 302D and 304 is shortened.

A central part of the line electrode 302D and a central part of the line electrode 303D are adjacent to each other in the X-axis direction and are magnetically coupled to each other. The line electrodes 301 and 302D are adjacent to each other in the Y-axis direction and are electrically coupled to each other. The line electrodes 303D and 304 are adjacent to each other in the Y-axis direction and are electrically coupled to each other.

The ground electrode 310D is disposed between the line electrodes 301, 302D, 303D, and 304 and the switches Sw31 and Sw32. The ground electrode 310D is connected to a ground terminal (not illustrated). The ground electrode 310D forms a ground point.

The via conductor V31D passes through the ground electrode 310D and connects the line electrode 302D and the switch Sw31. The via conductor V31D is insulated from the ground electrode 310D. The via conductor V31D forms the inductor L31. The capacitor electrode 311D faces the line electrode 302D in the Z-axis direction. The via conductor V32D connects the capacitor electrode 311D and the ground electrode 310D. The line electrode 302D and the capacitor electrode 311D form the capacitor C31.

The via conductor V34D passes through the ground electrode 310D and connects the line electrode 303D and the switch Sw32. The via conductor V34D is insulated from the ground electrode 310D. The via conductor V34D forms the inductor L32. The capacitor electrode 312D faces the line electrode 303D in the Z-axis direction. The via conductor V33D connects the capacitor electrode 312D and the ground electrode 310D. The line electrode 303D and the capacitor electrode 312D form the capacitor C32.

FIG. 44 is a perspective view of structure of a filter 3E according to Modification Example 5 of Embodiment 3. The structure of the filter 3E is a configuration in which the line electrodes 302D and 303D, the ground electrode 310D, and the via conductors V31D and V34D in FIG. 43 are replaced with line electrodes 302E and 303E, a ground electrode 310E, and via conductors V31E and V34E, respectively, and positions of the respective switches Sw31 and Sw32 are changed. Since the configurations are similar except for these, the description will not be repeated.

As illustrated in FIG. 44, the line electrodes 302E and 303E each have a band shape and form the distributed constant lines Rs32 and Rs33, respectively. Each of the line electrodes 302E and 303E is wound around a central axis (not illustrated) extending in the Z-axis direction and is formed in an L-shape. In comparison with the line electrode 302D in FIG. 43, the line electrode 302E does not have a part that is not adjacent to the line electrodes 301 and 303E. In comparison with the line electrode 303D in FIG. 43, the line electrode 303E does not have a part that is not adjacent to the line electrodes 302E and 304.

A central part of the line electrode 302E and a central part of the line electrode 303E are adjacent to each other in the X-axis direction and are magnetically coupled to each other. The line electrodes 301 and 302E are adjacent to each other in the Y-axis direction and are electrically coupled to each other. The line electrodes 303E and 304 are adjacent to each other in the Y-axis direction and are electrically coupled to each other.

The ground electrode 310E is disposed between the line electrodes 301, 302E, 303E, and 304 and the switches Sw31 and Sw32. The ground electrode 310E is connected to a ground terminal (not illustrated). The ground electrode 310E forms a ground point.

The via conductor V31E passes through the ground electrode 310E and connects the line electrode 302E and the switch Sw31. The via conductor V31E is insulated from the ground electrode 310E. The via conductor V31E forms the inductor 131. The capacitor electrode 311D faces the line electrode 302E in the Z-axis direction. The line electrode 302E and the capacitor electrode 311D form the capacitor C31.

The via conductor V34E passes through the ground electrode 310E and connects the line electrode 303E and the switch Sw32. The via conductor 734E is insulated from the ground electrode 310E. The via conductor V34E forms the inductor L32. The capacitor electrode 312D faces the line electrode 303E in the Z-axis direction. The line electrode 303E and the capacitor electrode 312D form the capacitor C32.

In a distributed constant line, a part to which a first impedance element is connected and a part to which a second impedance element is connected need not be the same. By making the two parts different from each other, an electrode pattern of the distributed constant line when the first impedance element is in a conductive state can be made equivalent to λ/2 or λ/4. As a result, in comparison with characteristics of a filter when the two parts are the same, characteristics of a filter can be changed.

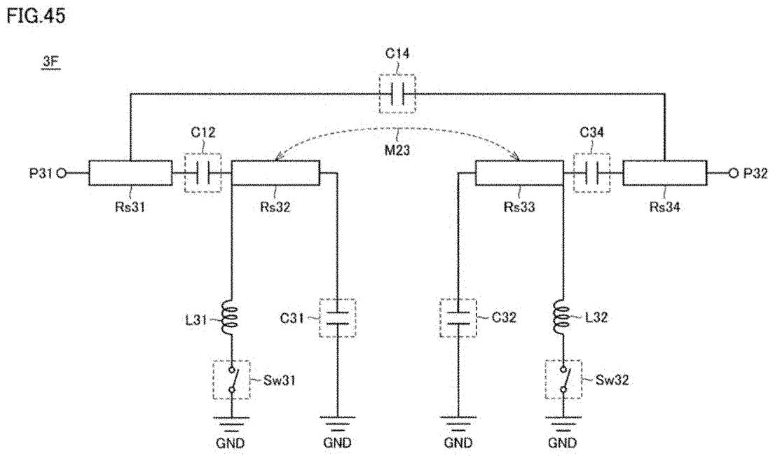

FIG. 45 is an equivalent circuit diagram of a filter 3F according to Modification Example 6 of Embodiment 3. A configuration of the filter 3F is a configuration in which the inductor L31 in FIG. 33 is connected to another end of the distributed constant line Rs32 and the inductor L32 is connected to another end of the distributed constant line Rs33. Since the configurations are similar except for these, the description will not be repeated.

FIG. 46 is a diagram showing bandpass characteristics of the filter 3F in FIG. 45. In FIG. 46, a solid line indicates bandpass characteristics of the filter 3F when the switches Sw31 and Sw32 in FIG. 45 are in a conductive state, and a dotted line indicates bandpass characteristics of the filter 3F when the switches Sw31 and Sw32 in FIG. 45 are in a non-conductive state. As shown in FIG. 46, by switching the switches Sw31 and Sw32, the bandpass characteristics of the filter 3F can be changed.

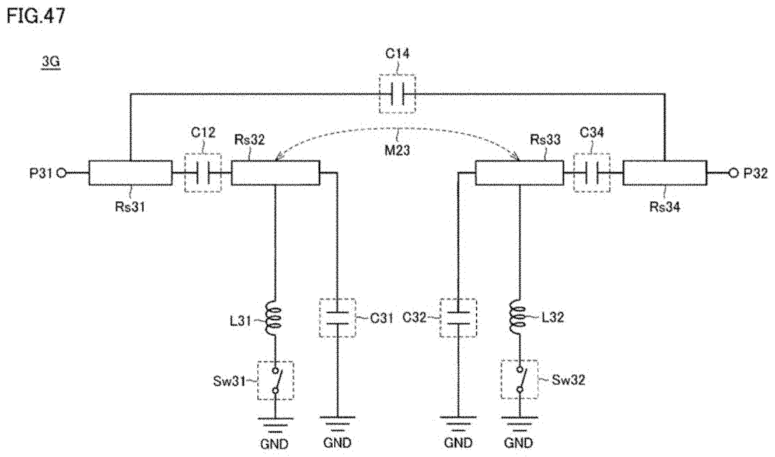

FIG. 47 is an equivalent circuit diagram of a filter 3G according to Modification Example 7 of Embodiment 3. A configuration of the filter 3G is a configuration in which the inductor L31 in FIG. 33 is connected to a central part of the distributed constant line Rs32 and the inductor L32 is connected to a central part of the distributed constant line Rs33. Since the configurations are similar except for these, the description will not be repeated.

FIG. 48 is a diagram showing bandpass characteristics of the filter 3G in FIG. 47. In FIG. 48, a solid line indicates bandpass characteristics of the filter 3G when the switches Sw31 and Sw32 in FIG. 47 are in a conductive state, and a dotted line indicates bandpass characteristics of the filter 3G when the switches Sw31 and Sw32 in FIG. 47 are in a non-conductive state. As shown in FIG. 48, by switching the switches Sw31 and Sw32, a highest frequency (high frequency end) in a pass band of the filter 3G can be changed.

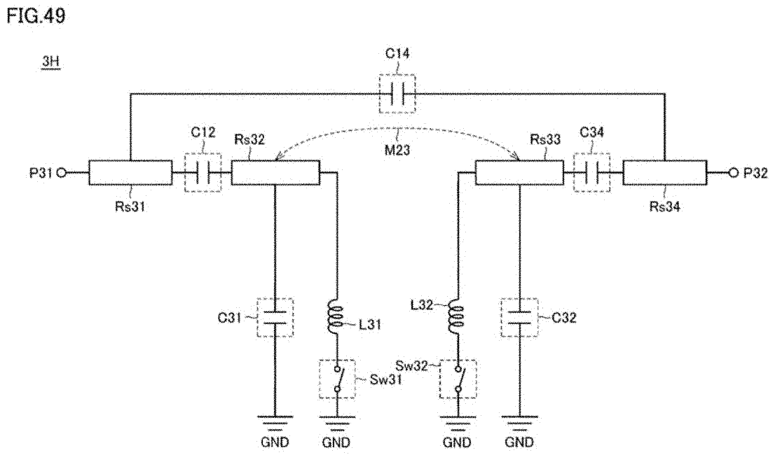

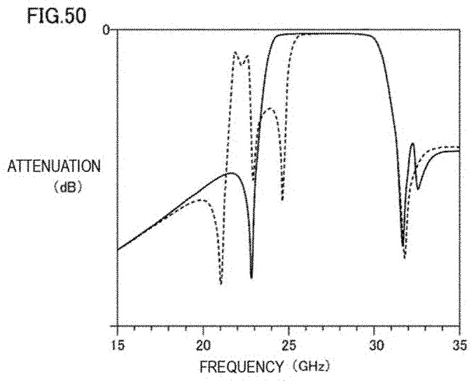

FIG. 49 is an equivalent circuit diagram of a filter 3H according to Modification Example 8 of Embodiment 3. A configuration of the filter 3H is a configuration in which the capacitor C31 in FIG. 33 is connected to a central part of the distributed constant line Rs32 and the capacitor C32 is connected to a central part of the distributed constant line Rs33. Since the configurations are similar except for these, the description will not be repeated.

FIG. 50 is a diagram showing bandpass characteristics of the filter 3H in FIG. 49. In FIG. 50, a solid line indicates bandpass characteristics of the filter 3H when the switches Sw31 and Sw32 in FIG. 49 are in a conductive state, and a dotted line indicates bandpass characteristics of the filter 3H when the switches Sw31 and Sw32 in FIG. 49 are in a non-conductive state. As shown in FIG. 50, by switching the switches Sw31 and Sw32, a lowest frequency (low frequency end) in a pass band of the filter 3H can be changed.

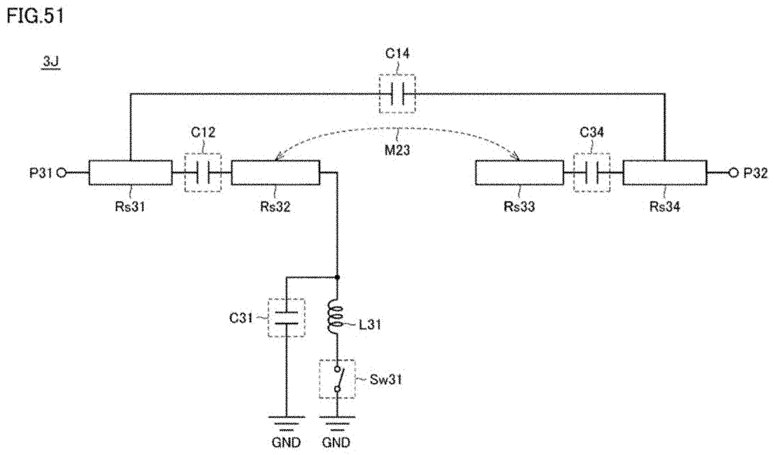

Among distributed constant lines included in a filter, the number of distributed constant lines to which two impedance elements are connected may be one. FIG. 51 is an equivalent circuit diagram of a filter 3J according to Modification Example 9 of Embodiment 3. A configuration of the filter 3J is a configuration obtained by removing the inductor L32, the switch Sw32, and the capacitor C32 from the filter 3 in FIG. 33. In the filter 3J, lengths of the respective distributed constant lines Rs31, Rs34, and Rs33 are preferably equal to each other. Since the configurations are similar except for these, the description will not be repeated.

FIG. 52 is a diagram showing bandpass characteristics of the filter 3J in FIG. 51. In FIG. 52, a solid line indicates bandpass characteristics of the filter 3J when the switch Sw31 in FIG. 51 is in a conductive state, and a dotted line indicates bandpass characteristics of the filter 3J when the switch Sw31 in FIG. 51 is in a non-conductive state.

As shown in FIG. 52, by switching the switch Sw31, the bandpass characteristics of the filter 3J can be changed while maintaining a pass band width. Further, since the number of circuit elements of the filter 3J is smaller than the number of circuit elements of the filter 3 in FIG. 33, a manufacturing cost of the filter 3J can be made lower than a manufacturing cost of the filter 3 and a size of the filter 3J can be made smaller than a size of the filter 3. The number of distributed constant lines to which two impedance elements are connected can be appropriately selected from among distributed constant lines included in a filter in accordance with a variation width of a desired pass band, attenuation at an attenuation pole outside the pass band, a manufacturing cost of the filter, and a size of the filter.

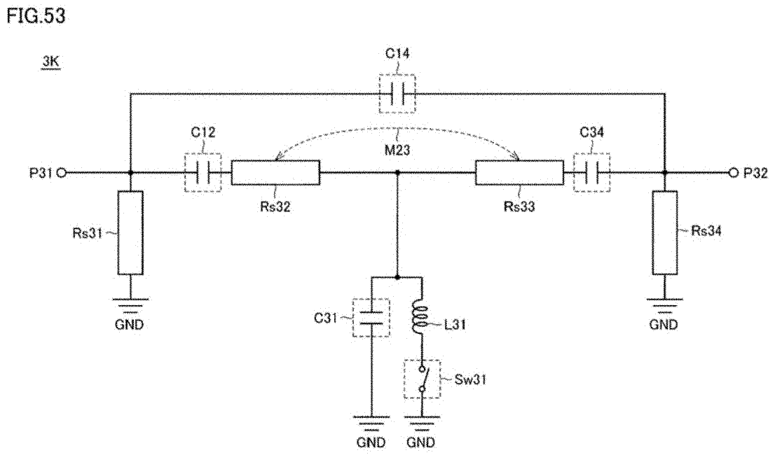

FIG. 53 is an equivalent circuit diagram of a filter 3K according to Modification Example 10 of Embodiment 3. A configuration of the filter 3K is a configuration in which each of the distributed constant lines Rs31 and Rs34 in FIG. 51 is connected to the ground point GND, the inductor L31 and the capacitor C31 are connected to the distributed constant line Rs33, and each of the distributed constant lines Rs31 to Rs34 functions as a λ/4 resonator. Since the configurations are similar except for these, the description will not be repeated.

As illustrated in FIG. 53, the distributed constant line Rs31 is connected between the ground point GND and a node between the terminal P31 and the capacitor C12. The distributed constant line Rs34 is connected between the ground point GND and a node between the terminal P32 and the capacitor C34.

FIG. 54 is a diagram showing bandpass characteristics of the filter 3K in FIG. 53. In FIG. 54, a solid line indicates bandpass characteristics of the filter 3K when the switch Sw31 in FIG. 53 is in a conductive state, and a dotted line indicates the bandpass characteristics of the filter 3K when the switch Sw31 in FIG. 53 is in a non-conductive state.

As shown in FIG. 54, by switching the switch Sw31, the bandpass characteristics of the filter 3K can be changed. Further, like the filter 3J, a manufacturing cost of the filter 3K can be reduced, and a size of the filter 3K can be reduced. Whether or not two impedance elements are shared among distributed constant lines can be appropriately selected in accordance with a variation width of a desired pass band, attenuation at an attenuation pole outside the pass band, a manufacturing cost of a filter, and a size of the filter.

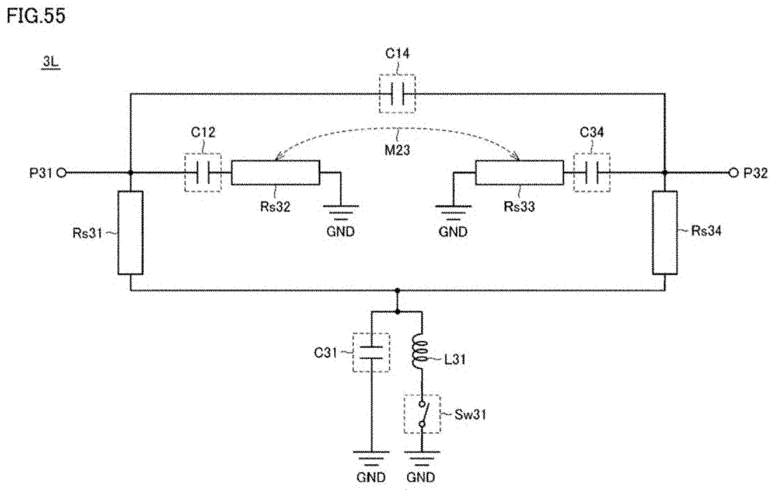

The configuration in which the two impedance elements are shared by the distributed constant lines is not limited to the filter 3K illustrated in FIG. 53. FIG. 55 is an equivalent circuit diagram of a filter 3L according to Modification Example 11 of Embodiment 3. A configuration of the filter 3L is a configuration in which each of the distributed constant lines Rs32 and Rs33 in FIG. 53 is connected to the ground point GND and in which the inductor L31 and the capacitor C31 are not connected to the distributed constant lines Rs32 and Rs33 but are connected to the distributed constant lines Rs31 and Rs34. Since the configurations are similar except for these, the description will not be repeated.

As illustrated in FIG. 55, the capacitor C31 is connected between the distributed constant line Rs31 and the ground point GND and is also connected between the distributed constant line Rs34 and the ground point GND. The inductor L31 and the switch Sw31 are connected in series in this order between the distributed constant line Rs31 and the ground point GND and are connected in series in this order between the distributed constant line Rs34 and the ground point GND.

As described above, according to the filter according to any one of Embodiment 3 and Modification Examples 1 to 11, it is possible to realize a reduction in size and cost of a filter capable of changing a pass band.

### Embodiment 4

In Embodiment 4, an antenna module including the filter according to any one of Embodiments 1 to 3 will be described.

FIG. 56 is a block diagram of an antenna module 400 according to Embodiment 4. As illustrated in FIG. 56, the antenna module 400 includes a radiating element 40, a digital-to-analog converter (DAC) 41, a transmitter 42, an amplifier 43, a mixer 44, a filter 4, and a power amplifier 45. The filter 4 may be any one of the filter 1 in FIG. 1, the filter 2 in FIG. 22, the filter 3 in FIG. 33, the filter 3A in FIG. 40, the filter 3B in FIG. 41, and the filter 3C in FIG. 42. A switch of the filter 4 is the switch Sw1 in FIGS. 1 and 22 or the switch Sw31 or Sw32 in FIG. 33 and FIGS. 40 to 42.

The DAC 41 converts a digital signal into an intermediate frequency (IF) signal and outputs the IF signal to the mixer 44. The transmitter 42 outputs a local signal to the mixer 44 via the amplifier 43. The mixer 44 generates a transmission signal having a desired frequency using the local signal and the IF signal and outputs the transmission signal to the filter 4. The filter 4 removes a signal (unnecessary wave) having a frequency other than the desired frequency from the signal from the mixer 44. The power amplifier 45 amplifies the transmission signal from the filter 4 and outputs the amplified transmission signal to the radiating element 40. The radiating element 40 radiates the transmission signal outside. Note that, the filter 4 may be connected between the power amplifier 45 and the radiating element 40.

FIG. 57 is a diagram showing bandpass characteristics of the antenna module 400 in FIG. 56. In FIG. 57, bandpass characteristics A41 indicate bandpass characteristics of the antenna module 400 when the switch of the filter 4 in FIG. 56 is in a conductive state, and bandpass characteristics A42 indicate bandpass characteristics of the antenna module 400 when the switch of the filter 4 in FIG. 56 is in a non-conductive state. Further, vertical lines at 23.5 GHz, 24 GHz, and 25.5 GHz indicate unnecessary waves generated when frequencies of transmission signals are 27.5 GHz, 28 GHz, and 29.5 GHz, respectively.

As shown in FIG. 57, when the frequencies of the transmission signals are included in the frequency band n257, the unnecessary waves generated at 24 GHz and 25.5 GHz can be removed by the filter 4 by bringing the switch of the filter 4 into the conductive state. When the frequencies of the transmission signals are included in the frequency band n258, the switch of the filter 4 is brought into the non-conductive state, thereby making it possible to remove unnecessary waves generated at 23.5 GHz.

As described above, according to the antenna module according to Embodiment 4, communication quality can be improved by changing a pass band of the filter in accordance with a frequency of a transmission signal.

### Embodiment 5

In Embodiment 5, a case where a switch of a filter according to the embodiment is formed inside a radio frequency element of an antenna module will be described.

FIG. 58 is a diagram illustrating cross-sectional structure of an antenna module 500 according to Embodiment 5. As illustrated in FIG. 58, the antenna module 500 includes a filter 5, a ground electrodes 511 and 512, a radiating element 520, a dielectric substrate 530, and a radio frequency integrated circuit (RFIC) 540 (radio frequency element). An equivalent circuit of the filter 5 is similar to that of the filter 1 in FIG. 1.

The ground electrodes 511 and 512 are formed inside the dielectric substrate 530 and are connected to a ground point (not illustrated). The radiating element 520 is disposed between the ground electrode 511 and an upper surface 531 of the dielectric substrate 530. The RFIC 540 is disposed on a bottom surface 532 of the dielectric substrate 530.

The filter 5 includes a line electrode 501, a capacitor electrode 502, a switch Sw5 (first switch), a via conductor V51 (first via conductor), and a via conductor V52. The line electrode 501 is disposed between the ground electrodes 511 and 512 and forms the distributed constant line Rs1. The line electrode 501 is connected to the radiating element 520. The capacitor electrode 502 is disposed between the line electrode 501 and the ground electrode 512. The line electrode 501 and the capacitor electrode 502 face each other in the Z-axis direction and form the capacitor C2.

The via conductor V51 connects the line electrode 501 to the switch Sw5. The via conductor 751 forms the inductor L1. The switch Sw5 is disposed inside the RFIC 540. The RFIC 540 supplies a radio frequency signal to the radiating element 520 via the filter 5. In the antenna module 500, since the switch Sw5 of the filter 5 can be integrated inside the RFIC 540, the antenna module 500 can be reduced in size. Note that, the filter 5 and the radiating element 520 may be connected to each other via the RFIC 540.

As described above, according to the antenna module according to Embodiment 5, communication quality can be improved by changing a pass band of the filter in accordance with a frequency of a transmission signal, and the antenna module can be reduced in size.

### Embodiment 6

In Embodiment 6, a description will be given of a configuration in which a mechanism for changing a pass band of the filter according to any one of Embodiments 1 to 3 is applied to a radiating element to change reflection characteristics of the radiating element.

FIG. 59 is an equivalent circuit diagram of a radiating element 6 according to Embodiment 6. A configuration of the radiating element 6 is a configuration in which, in FIG. 1, the terminals P1 and P2 are removed from the filter 1, the distributed constant line Rs1 is replaced with an antenna electrode 60, and the switch Sw1 is formed inside an RFIC 640. Since the configurations are similar except for these, the description will not be repeated.

As illustrated in FIG. 59, the antenna electrode 60 is connected to the RFIC 640. Note that, the switch Sw1 may be formed outside the RFIC 640. Further, a capacitor (capacitance element) may be connected between the inductor L1 and the antenna electrode 60.

FIG. 60 is a perspective view of structure of the radiating element 6 in FIG. 59. FIG. 61 is a plan view of the radiating element 6 in FIG. 59 viewed in the Y-axis direction. As illustrated in FIG. 60 and FIG. 61, the radiating element 6 includes the antenna electrode 60, a capacitor electrode 602, a ground electrode 610, via conductors V61, V62, and V63, a dielectric substrate 630, and the switch Sw1. The antenna electrode 60, the capacitor electrode 602, the ground electrode 610, and the via conductors V61 to V63 are formed inside the dielectric substrate 630.

The ground electrode 610 is disposed between the antenna electrode 60 and the switch Sw1. The ground electrode 610 and the switch Sw1 are connected to a ground terminal (not illustrated). The ground electrode 610 forms a ground point.

The via conductor V61 passes through the ground electrode 610 and connects one end in the X-axis direction of the antenna electrode 60 and the switch Sw1. The via conductor V61 is insulated from the ground electrode 610. The via conductor V61 forms the inductor L1.

The capacitor electrode 602 faces another end in the X-axis direction of the antenna electrode 60 in the Z-axis direction. The via conductor V62 connects the capacitor electrode 602 and the ground electrode 610. The antenna electrode 60 and the capacitor electrode 602 form the capacitor C2.

The via conductor V63 passes through the ground electrode 610 and connects a central part of the antenna electrode 60 and the RFIC 640. The via conductor V63 is insulated from the ground electrode 610.

Note that, a part of the antenna electrode 60 connected to the RFIC 640 need not be the central part of the antenna electrode 60. The capacitor electrode 602, with respect to a height from the ground electrode 610 in the Z-axis direction, may be disposed at substantially the same height as that of the antenna electrode 60 so as to be adjacent to the antenna electrode 60. The capacitor electrode 602 may face either the central part or an end portion of the antenna electrode 60. The via conductor 761 may be connected to either the central part or the end portion of the antenna electrode 60. A part of the antenna electrode 60 that the capacitor electrode 602 faces may be the same as or different from a part of the antenna electrode 60 connected to the via conductor V61.

FIG. 62 is a diagram showing reflection characteristics (a relationship between frequency and return loss (RL)) of the radiating element 6 in FIGS. 59 to 61. In FIG. 62, a solid line indicates reflection characteristics of the radiating element 6 when the switch Sw1 in FIG. 59 is in a conductive state, and a dotted line indicates reflection characteristics of the radiating element 6 when the switch Sw1 in FIG. 59 is in a non-conductive state. The larger reflection loss means the larger ratio of signals radiated outside from the antenna electrode 60 among radio frequency signals supplied from the RFIC 640 to the antenna electrode 60. As shown in FIG. 62, by switching the switch Sw1, the reflection characteristics of the radiating element 6 can be changed.

As described above, according to the radiating element according to Embodiment 6, it is possible to achieve a reduction in size and cost of a radiating element capable of changing reflection characteristics.

It is also planned that each embodiment disclosed herein will be implemented in appropriate combinations to such an extent that no contradiction occurs. The embodiments disclosed herein are to be considered in all respects as illustrative and not restrictive. The scope of the present disclosure is defined not by the above description but by the claims and is intended to include meanings equivalent to the claims and all modifications within the scope of the claims.

1. A filter, comprising:
a first distributed constant line;
a first impedance element;
a second impedance element; and
a first switch, wherein
the first impedance element and the first switch are connected in series between the first distributed constant line and a ground point, and
the second impedance element is connected between the first distributed constant line and the ground point.

2. The filter of claim 1, wherein
the first impedance element includes a first inductor, and
the second impedance element includes a first capacitor.

3. The filter of claim 2, wherein
the first distributed constant line is formed of a first line electrode having a band-shape,
the ground point is formed of a ground conductor portion including a first ground electrode, and
the first inductor is connected between the first line electrode and the first switch.

4. The filter of claim 1, further comprising:
a first terminal;
a second terminal;
a second distributed constant line that is magnetically coupled to the first distributed constant line;
a third distributed constant line; and
a fourth distributed constant line that is electrically coupled to the third distributed constant line, wherein
the first distributed constant line and the second distributed constant line are electrically connected to the third distributed constant line and the fourth distributed constant line, respectively, and
the first terminal and the second terminal are electrically connected to the first distributed constant line and the second distributed constant line, respectively, or to the third distributed constant line and the fourth distributed constant line, respectively.

5. The filter of claim 4, wherein
the first impedance element and the first switch are connected in series between one of both end portions of the first distributed constant line and the ground point, and
the second impedance element is connected between one of the end portions of the first distributed constant line and the ground point.

6. The filter of claim 1, further comprising:
a first terminal;
a second terminal;
a second distributed constant line that is electrically coupled to the first distributed constant line;
a third distributed constant line; and
a fourth distributed constant line that is magnetically coupled to the third distributed constant line, wherein
the first distributed constant line and the second distributed constant line are electrically connected to the third distributed constant line and the fourth distributed constant line, respectively, and
the first terminal and the second terminal are electrically connected to the first distributed constant line and the second distributed constant line, respectively, or to the third distributed constant line and the fourth distributed constant line, respectively.

7. The filter of claim 6, wherein
the first impedance element and the first switch are connected in series between a central part of the first distributed constant line and the ground point, and
the second impedance element is connected between the central part of the first distributed constant line and the ground point.

8. The filter of claim 6, wherein
the first impedance element and the first switch are connected in series between a central part of the first distributed constant line and the ground point, and
the second impedance element is connected between an end portion of the first distributed constant line and the ground point.

9. The filter of claim 6, wherein
the first impedance element and the first switch are connected in series between an end portion of the first distributed constant line and the ground point, and
the second impedance element is connected between a central part of the first distributed constant line and the ground point.

10. The filter of claim 6, wherein
the first impedance element and the first switch are connected in series between one end of the first distributed constant line and the ground point, and
the second impedance element is connected between another end of the first distributed constant line and the ground point.

11. The filter of claim 4, wherein
the first impedance element and the first switch are connected in series between the second distributed constant line and the ground point, and
the second impedance element is connected between the second distributed constant line and the ground point.

12. The filter of claim 4, further comprising:
a third impedance element;
a fourth impedance element; and
a second switch, wherein
the third impedance element and the second switch are connected in series between the second distributed constant line and the ground point, and
the fourth impedance element is connected between the second distributed constant line and the ground point.

13. The filter of claim 4, wherein
a length of the first distributed constant line is identical to a length of the second distributed constant line and is different from a length of the third distributed constant line, and
a length of the fourth distributed constant line is equal to the length of the third distributed constant line.

14. The filter of claim 13, wherein each of the first distributed constant line and the second distributed constant line is formed in an L shape.

15. The filter of claim 1, further comprising a specific line electrode in which the first distributed constant line is formed as a stub.

16. An antenna module comprising:
a radiating element;
a filter according comprising
a first distributed constant line;
a first impedance element;
a second impedance element; and
a first switch, wherein
the first impedance element and the first switch are connected in series between the first distributed constant line and a ground point, and
the second impedance element is connected between the first distributed constant line and the ground point; and
a radio frequency element configured to supply a radio frequency signal to the radiating element via the filter.

17. The antenna module of claim 16, wherein
the antenna module transmits a first signal in a first frequency band and a second signal in a second frequency band from the radiating element, and
when the antenna module transmits the first signal, the first switch is brought into a non-conductive state, and when the antenna module transmits the second signal, the first switch is brought into a conductive state.

18. The antenna module of claim 16, wherein
the first switch is disposed inside the radio frequency element.

19. A radiating element, comprising:
an antenna electrode;
a first impedance element;
a second impedance element; and
a first switch, wherein
the first impedance element and the first switch are connected in series between the antenna electrode and a ground point, and
the second impedance element is connected between the antenna electrode and the ground point.
